(19) United States
(12) Patent Application Publication
(10) Pub. No.: US 2026/0184989 A1
(43) Pub. Date: Jul. 2, 2026

(54) FLUORIDE PHOSPHOR, METHOD FOR MANUFACTURING FLUORIDE PHOSPHOR, AND LIGHT-EMITTING DEVICE

(71) Applicant: NICHIA CORPORATION, Anan-shi (JP)

(72) Inventors: Kenichi AOYAGI, Itano-gun (JP); Tomokazu YOSHIDA, Anan-shi (JP); Kazuya NISHIMATA, Anan-shi (JP)

(73) Assignee: NICHIA CORPORATION, Anan-shi (JP)

(21) Appl. No.: 19/428,596

(22) Filed: Dec. 22, 2025

(30) Foreign Application Priority Data
Dec. 26, 2024 (JP) 2024-230557

(51) Int. Cl. C09K 11/72; H10H 20/851

(52) U.S. Cl. CPC C09K 11/727; H10H 20/8512

(57) ABSTRACT

A fluoride phosphor includes fluoride particles and a phosphate disposed on at least a part of a surface of the fluoride particles. The phosphate contains at least zinc in its composition. The fluoride particles have a composition containing an alkali metal, Mn, F, and an element M that includes at least one element selected from the group consisting of Group 4 elements, Group 13 elements, and Group 14 elements, and wherein in the composition of the fluoride particles, when the number of moles of the alkali metal is 2, the number of moles of Mn is greater than 0 and less than 0.2, the number of moles of the element M is greater than 0.8 and less than 1, and the number of moles of F is greater than 5 and less than 7.

### CROSS-REFERENCE TO RELATED APPLICATION

This application claims priority to Japanese Patent Application No. 2024-230557, filed on Dec. 26, 2024, the disclosure of which is hereby incorporated by reference in its entirety.

### TECHNICAL FIELD

The present disclosure relates to a fluoride phosphor, a method for manufacturing the fluoride phosphor, and a light-emitting device.

### BACKGROUND

Light-emitting devices in which a light-emitting element and a phosphor are combined are used in a wide range of fields, such as in lighting, in-vehicle lighting, displays, and liquid crystal backlights. For example, a phosphor used in a light-emitting device in a liquid crystal backlight application is needed to have high color purity, that is, the full width at half maximum of the emission peak needs to be narrow. A fluoride phosphor in which Mn is added is known as a red luminous phosphor having a narrow full width at half maximum of the emission peak.

For example, Japanese Patent Publication No. 2020-019921 describes phosphor particles in which inorganic fine particles are adhered to the surface of an Mn-added fluoride red phosphor.

### SUMMARY

In a light-emitting device including a fluoride phosphor to which Mn is added, when the light-emitting device is used in a high-temperature and high-humidity environment, the reliability of the device may be reduced because of a decrease in luminous flux or the like. An object of an aspect of the present disclosure is to provide a fluoride phosphor that can improve reliability of a light-emitting device in a high-temperature and high-humidity environment, and a method for manufacturing the fluoride phosphor.

A first aspect is a fluoride phosphor including first fluoride particles and a phosphate disposed on at least a part of a surface of the first fluoride particles. The phosphate may contain at least zinc in its composition. The first fluoride particles may have a composition containing an element M, an alkali metal, manganese ions (Mn), and a fluorine atom (F), wherein the element M includes at least one selected from the group consisting of Group 4 elements, Group 13 elements, and Group 14 elements, and wherein when the number of moles of the alkali metal is 2, the number of moles of manganese is in a range of more than 0 and less than 0.2, the number of moles of the element M is in a range of more than 0.8 and less than 1, and the number of moles of the fluorine atom is in a range of more than 5 and less than 7.

A second aspect is a method for manufacturing a fluoride phosphor, the method including: providing first fluoride particles having a composition containing an element M, an alkali metal, manganese ions (Mn), and a fluorine atom (F), wherein the element M includes at least one selected from the group consisting of Group 4 elements, Group 13 elements, and Group 14 elements, and when the number of moles of the alkali metal is 2, the number of moles of manganese is in a range of more than 0 and less than 0.2, the number of moles of the element M is in a range of more than 0.8 and less than 1, and the number of moles of the fluorine atom is in a range of more than 5 and less than 7; and bringing the first fluoride particles, phosphate ions, and at least one metal ion containing at least one selected from the group consisting of magnesium (Mg), calcium (Ca), strontium (Sr), and zinc (Zn), into contact with each other in a liquid medium containing the first fluoride particles to obtain a fluoride phosphor in which a phosphate is adhered to the first fluoride particles.

A third aspect is a light-emitting device including a fluorescent member including the fluoride phosphor according to the first aspect and a resin, and a light-emitting element having a light emission peak wavelength in a wavelength range of 380 nm to 485 nm.

According to an aspect of the present disclosure, a fluoride phosphor that can improve reliability of a light-emitting device in a high-temperature and high-humidity environment and a method for manufacturing the fluoride phosphor can be provided.

### BRIEF DESCRIPTION OF DRAWINGS

FIG. 1 is a schematic sectional view illustrating an example of a light-emitting device including a fluoride phosphor.

FIG. 2A is an example of a scanning electron microscope (SEM) image of a fluoride phosphor according to Example 1.

FIG. 2B is an example of a high magnification SEM image of the fluoride phosphor according to Example 1.

FIG. 3A is an example of an SEM image of a fluoride phosphor according to Example 2.

FIG. 3B is an example of a high magnification SEM image of the fluoride phosphor according to Example 2.

FIG. 4A is an example of an SEM image of a fluoride phosphor according to Example 3.

FIG. 4B is an example of a high magnification SEM image of the fluoride phosphor according to Example 3.

FIG. 5A is an example of an SEM image of a fluoride phosphor according to Example 6.

FIG. 5B is an example of a high magnification SEM image of the fluoride phosphor according to Example 6.

FIG. 6A is an example of an SEM image of a fluoride phosphor according to Example 7.

FIG. 6B is an example of a high magnification SEM image of the fluoride phosphor according to Example 7.

FIG. 7A is an example of an SEM image of a fluoride phosphor according to Example 9.

FIG. 7B is an example of a high magnification SEM image of the fluoride phosphor according to Example 9.

### DETAILED DESCRIPTION

In the present specification, the word “step” herein includes not only an independent step, but also a step that cannot be clearly distinguished from another step if the anticipated purpose of the step is achieved. When a plurality of substances applicable to a single component in a composition are present, the content of the single component in the composition means the total amount of the plurality of substances present in the composition, unless otherwise specified. Furthermore, with respect to an upper limit and a lower limit of numerical ranges described herein, the numerical values exemplified as the numerical range can be freely selected and combined. In the present specification, a plurality of elements separated by commas (,) in a formula representing the composition of the phosphor or light-emitting material means that at least one element among the plurality of elements is contained in the composition. In a formula representing the composition of the phosphor, any element preceding the colon (:) represents a host crystal, and any element following the colon (:) represents an activating element. Note that herein, the relationship between a color name and chromaticity coordinates, the relationship between a wavelength range of light and a color name of monochromatic light are in accordance with JIS Z8110. The half width of a phosphor or a light-emitting material means a wavelength width (full width at half maximum: FWHM) in an emission spectrum at which an emission intensity is 50% of a maximum emission intensity in the emission spectrum of the phosphor or the light-emitting material. Embodiments of the present invention are described below in detail. The embodiments presented below exemplify a fluoride phosphor, a method for manufacturing the fluoride phosphor, and a light-emitting device, which all embody the technical concept of the present invention, but the present invention is not limited to the fluoride phosphor, the method for manufacturing the fluoride phosphor, or the light-emitting device presented below.

### Fluoride Phosphor

The fluoride phosphor includes fluoride particles (hereinafter, also referred to as first fluoride particles) having a specific composition and a phosphate disposed on at least a part of the surface of the first fluoride particles. The phosphate may contain at least zinc as a metal ion in the composition. The first fluoride particles may contain: an element M including at least one selected from the group consisting of Group 4 elements, Group 13 elements, and Group 14 elements; an alkali metal; manganese; and a fluorine atom in the composition. When the number of moles of the alkali metal is 2, the composition of the first fluoride particles may be such that the number of moles of manganese is in a range of more than 0 and less than 0.2, the number of moles of the element M is in a range of more than 0.8 and less than 1, and the number of moles of fluorine atoms is in a range of more than 5 and less than 7.

When the fluoride phosphor has a configuration in which the phosphate containing zinc is disposed on at least a part of the surface of the first fluoride particles having a specific composition, reliability in the light-emitting device including the fluoride phosphor, in particular, reliability in a high-temperature and high-humidity environment can be improved. The reason for this is assumed to be as follows, for example. In a light-emitting device formed by encapsulating a light-emitting element with a resin containing a fluoride phosphor, a phosphate is disposed on at least a part of the surface of the first fluoride particles constituting the fluoride phosphor, and thus a contact area between the resin and the first fluoride particles is reduced. This is assumed to suppress the reaction between the resin and the first fluoride particles under high temperature and high humidity, thereby suppressing the deterioration of the resin, and thus preventing or reducing a decrease in luminous flux or the like, and improving the reliability as a light-emitting device. In addition, it can be assumed that when the phosphate contains a zinc ion as a metal ion, the phosphate is more uniformly disposed, and the reliability of a light-emitting device can be more effectively improved.

The first fluoride particles contained in the fluoride phosphor may contain at least a phosphor activated by manganese (Mn), and may be composed only of the phosphor activated by manganese (Mn). The composition of the first fluoride particles is such that when the number of moles of the alkali metal is 2, the number of moles of manganese may be in a range of more than 0 and less than 0.2, and is preferably in a range of 0.01 to 0.12. The composition of the first fluoride particles is also such that when the number of moles of the alkali metal is 2, the number of moles of the element M may be in a range of more than 0.8 and less than 1, and is preferably in a range of 0.88 to 0.99. The composition of the first fluoride particles is also such that when the number of moles of the alkali metal is 2, the number of moles of fluorine atom may be in a range of more than 5 and less than 7, and is preferably in a range of 5.9 to 6.1. The composition of the first fluoride particles may be measured, for example, by inductively coupled plasma (ICP) emission spectroscopy.

The alkali metal in the composition of the first fluoride particles may include at least one selected from the group consisting of lithium (Li), sodium (Na), potassium (K), rubidium (Rb), and cesium (Cs). The alkali metal may include at least potassium (K), and at least one selected from the group consisting of lithium (Li), sodium (Na), rubidium (Rb), and cesium (Cs). A ratio of the number of moles of K to the total number of moles of the alkali metal in the composition may be, for example, 0.90 or greater, and is preferably 0.95 or greater, or 0.97 or greater. The upper limit of the ratio of the number of moles of K may be, for example, 1 or less, or 0.995 or less. In the composition of the first fluoride particles, some of the alkali metals may be substituted with ammonium ions (NH₄⁺). When some of the alkali metals are substituted with ammonium ions, the ratio of the number of moles of the ammonium ions to the total number of moles of the alkali metal in the composition may be, for example, 0.10 or less, and is preferably 0.05 or less, or 0.03 or less. The lower limit of the ratio of the number of moles of the ammonium ion may be, for example, greater than 0, and may be preferably 0.005 or greater.

The element M in the composition of the first fluoride particles contains at least one selected from the group consisting of Group 4 elements, Group 13 elements, and Group 14 elements. Examples of Group 4 elements include titanium (Ti), zirconium (Zr), and hafnium (Hf), and at least one selected from the group consisting of these elements may be included. Examples of Group 13 elements include boron (B), aluminum (Al), gallium (Ga), indium (In), and thallium (Tl), and at least one selected from the group consisting of these elements may be included. Examples of Group 14 elements include carbon (C), silicon (Si), germanium (Ge), and tin (Sn), and at least one selected from the group consisting of these elements may be included. The element M may contain at least one element from the Group 14 elements, may preferably contain Si and/or Ge, and may more preferably contain at least Si. In addition, the element M may contain at least one of the Group 13 elements and at least one of the Group 14 elements, and may preferably contain at least one selected from Al, Si, and Ge, and may more preferably contain Al and/or Si.

A first composition, which is an aspect of the composition of the first fluoride particles, may contain, as the element M, at least one selected from the group consisting of Group 4 elements and Group 14 elements, preferably at least one selected from the group consisting of Group 14 elements, and more preferably Si and/or Ge, and still more preferably at least Si. In addition, the first composition of the first fluoride particles may have a total number of moles of Si, Ge, and Mn in a range of 0.9 to 1.1, preferably of 0.95 to 1.05, or of 0.97 to 1.03, per 2 moles of the alkali metal.

The first composition of the first fluoride particles may be a composition represented by Formula (1) set forth below.

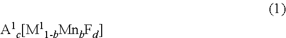

In Formula (1), A¹ may include at least one selected from the group consisting of Li, Na, K, Rb, and Cs. M¹ includes Si and/or Ge and may further include at least one element selected from the group consisting of Group 4 elements and Group 14 elements. Mn may be a tetravalent Mn ion. b satisfies 0<b<0.2, c is the absolute value of the charge of the [M¹_{1-b}Mn_{b}F_{d}] ion, and d satisfies 5<d<7.

A¹ in Formula (1) includes at least K and may further include at least one selected from the group consisting of Li, Na, Rb, and Cs. Also, some of the A¹ may be substituted with ammonium ions (NH₄⁺). When some of the A¹ are substituted with ammonium ions, the ratio of the number of moles of the ammonium ions to the total number of moles of A¹ in the composition may be, for example, 0.10 or less, and preferably 0.05 or less or 0.03 or less. The lower limit of the ratio of the number of moles of the ammonium ion may be, for example, greater than 0, and may be preferably 0.005 or greater.

In Formula (1), b is preferably in a range of 0.005 to 0.15, of 0.01 to 0.12, or of 0.015 to 0.1. c may be in a range of 1.8 to 2.2, and is preferably in a range of 1.9 to 2.1, or of 1.95 to 2.05. In addition, d may be in a range of 5.5 to 6.5, of 5.9 to 6.1, of 5.92 to 6.05, or of 5.95 to 6.025.

The first fluoride particles having the first composition may have a first theoretical composition represented by Formula (1a) set forth below.

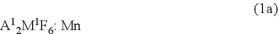

In Formula (1a), A¹ may include at least one selected from the group consisting of Li, Na, K, Rb, and Cs. M¹ includes Si and/or Ge and may further include at least one element selected from the group consisting of Group 4 elements and Group 14 elements. Mn may be a tetravalent Mn ion.

A second composition, which is an aspect of the composition of the first fluoride particles, may contain, as the element M, at least one selected from the group consisting of Group 4 elements and Group 14 elements and at least one selected from the group consisting of Group 13 elements, and preferably at least one selected from the group consisting of Group 14 elements and at least one selected from the group consisting of Group 13 elements, and more preferably at least Si and Al. In addition, the second composition of the first fluoride particles may have a total number of moles of Si, Al, and Mn in a range of 0.9 to 1.1, preferably of 0.95 to 1.05, or of 0.97 to 1.03, per 2 moles of the alkali metal. Further, the second composition of the first fluoride particles may have a number of moles of Al in a range of more than 0 and 0.1, and preferably in a range of more than 0 and 0.03, of 0.002 to 0.02, or of 0.003 to 0.015, per 2 moles of the alkali metal.

The second composition of the first fluoride particles may be a composition represented by Formula (2) set forth below.

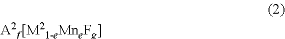

A² in Formula (2) includes at least K and may further include at least one element selected from the group consisting of Li, Na, Rb, and Cs. M² includes at least Si and Al and may further include at least one element selected from the group consisting of Group 4 elements, Group 13 elements, and Group 14 elements. Mn may be a tetravalent Mn ion. e satisfies 0<e<0.2, f is the absolute value of the charge of the [M²₁₋ₑMnₑF_{g}] ion, and g satisfies 5<g<7.

Also, some of the A² in Formula (2) may be substituted with ammonium ions (NH₄⁺). When some of the A² are substituted with ammonium ions, the ratio of the number of moles of the ammonium ions to the total number of moles of A² in the composition may be, for example, 0.10 or less, and is preferably 0.05 or less or 0.03 or less. The lower limit of the ratio of the number of moles of the ammonium ion may be, for example, greater than 0, and may be preferably 0.005 or greater.

In Formula (2), e is preferably in a range of 0.005 to 0.15, of 0.01 to 0.12, or of 0.015 to 0.1. f may be, for example, in a range of 1.8 to 2.2, and is preferably in a range of 1.9 to 2.1, or of 1.95 to 2.05. g may be in a range of 5.5 to 6.5, of 5.9 to 6.1, of 5.92 to 6.05, or of 5.95 to 6.025.

The first fluoride particles of the second composition may have a second theoretical composition represented by Formula (2a) set forth below.

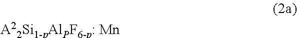

A² in Formula (2a) includes at least K and may further include at least one element selected from the group consisting of Li, Na, Rb, and Cs. Here, p satisfies 0<p<1. Mn may be a tetravalent Mn ion.

The first fluoride particles having the second composition may have protrusion and recession, grooves, or the like in the surface of the particles. The state of the particle surface can be evaluated by, for example, measuring the angle of repose of a powder formed from the first fluoride particles. The angle of repose of the powder formed from the first fluoride particles having the second composition may be, for example, 70° or less, and is preferably 65° or less, or 60° or less. The lower limit of the angle of repose is, for example, 30° or higher. The angle of repose is measured by, for example, a funnel method.

When the phosphate is disposed on the surface of the first fluoride particles that have the second composition having protrusions and recessions, grooves or the like, on the surface, for example, the contact area between the first fluoride particles and the phosphate increases. Thus, a strong bond is obtained between the first fluoride particles and the phosphate, and the phosphate can be disposed on the surface of the first fluoride particles in a state in which it is difficult to separate the phosphate with an external force. In addition, even when a relatively small amount of a raw material for the phosphate is used, a sufficient amount of the phosphate can be disposed on the surface of the first fluoride particles. Similarly, when the surface of the first fluoride particles is covered with a specific oxide, and further, when the oxide covers the first fluoride particles via a phosphate, the contact area between the first fluoride particles and the oxide increases when the first fluoride particles are covered with the specific oxide because the first fluoride phosphor has protrusion and recession, grooves, or the like on the surface. Thus, the bond between the first fluoride particles and the oxide becomes stronger, and the first fluoride particles can be covered with a film of the oxide which is hardly peeled off by an external force at the time of manufacturing the light-emitting device. Even when a relatively small amount of an oxide raw material is used, the first fluoride particles can be covered with a sufficient amount of oxide.

From the viewpoint of improving luminance, the volume-based median size of the first fluoride particles may be, for example, in a range of 5 μm to 90 μm, and is preferably in a range of 10 μm to 70 μm or of 15 μm to 50 μm. From the viewpoint of improving luminance, the particle size distribution of the first fluoride particles may exhibit a single peak, and preferably exhibit a single peak with a narrow distribution range. Specifically, in the volume-based particle size distribution, when a particle size corresponding to a cumulative volume of 10% from the small diameter side is denoted by D10, and a particle size corresponding to a cumulative volume of 90% is denoted by D90, a ratio (D90/D10) of D90 to D10 may be 3.0 or less, for example. Note that the volume-based median size is a particle size corresponding to a cumulative volume of 50% from the small size side in the volume-based particle size distribution, and the volume-based particle size distribution is measured using a laser diffraction particle size distribution measuring device.

The first fluoride particles may have a surface region having a manganese concentration lower than the manganese concentration in the inner region. The first fluoride particles are a phosphor activated by manganese ions, and it is assumed that manganese ions contained in the first fluoride particles react with moisture in the external environment in the surface region of the particles to produce manganese dioxide, and the particle surface is colored black, resulting in a decrease in light emission output or a chromaticity shift. However, it is assumed that, when the manganese concentration in the surface region of the first fluoride particles is kept to be lower than the manganese concentration in the inner region, the generation of manganese dioxide on the particle surface is suppressed, the decrease in light emission output and the chromaticity shift are suppressed over a long period of time, and the reliability of a light-emitting device is further improved.

The surface region may be partitioned from the inner region by a clear interface like a two layer structure, or may be in a form in which the manganese concentration gradually decreases from the inside to the outside of the surface region without being partitioned from the inner region by a clear interface. The average value of the concentration of manganese present in the surface region of the first fluoride particles may be, for example, 30% mass or less, preferably 25 mass % or less, or 20 mass % or less, with respect to the average value of the concentration of manganese in the inner region. The manganese concentration in the surface region may be, for example, 0.5 mass % or more of the manganese concentration in the inner region. The thickness of the surface region may be, for example, about 1/10 to 1/50 of the average particle size, although it depends on the particle size of the fluoride phosphor. Specifically, for example, when the average particle size of the first fluoride particles is in a range of 20 μm to and 40 μm, the thickness of the surface region may be, for example, 2 μm or less. The first fluoride particles having a surface region having a manganese concentration lower than the manganese concentration in the inner region can be manufactured, for example, by referring to a manufacturing method described in Japanese Patent Publication No. 2015-042705.

The fluoride phosphor may contain a phosphate (metal phosphate) disposed on at least a part of the surface of the first fluoride particles. The phosphate disposed on the surface of the first fluoride particles may have a particle shape or a film shape. Here, the phosphate having a particle shape means that the individual shapes of the phosphate to be disposed have similar shapes, and the outer edge of one phosphate can be distinguished from the outer edge of another phosphate. The shape of the phosphate may be, for example, a spherical shape, a rod shape, or the like. The phosphate having a film shape means that the outer edge of each phosphate has an irregular shape. The shape of the phosphate may be preferably a film shape. When the phosphate is disposed in a film shape on the surface of the first fluoride particles, the surface of the first fluoride particles can be more uniformly covered. The coverage percentage of the first fluoride particles by the phosphate in the fluoride phosphor may be, for example, 50% or more, preferably 80% or more, or 90% or more. The coverage percentage of the first fluoride particles by the phosphate is calculated as the ratio of the area, in which the phosphate is disposed, to the surface area of the first fluoride particles.

The phosphate disposed on at least a part of the surface of the first fluoride particles may contain at least zinc (Zn) ions as metal ions. That is, the phosphate may contain at least zinc phosphate (for example, Zn₃(PO₄)₂). When the phosphate contains zinc ions, the phosphate tends to more uniformly adhere to the surface of the first fluoride particles.

The phosphate may contain metal ions other than zinc ions. Examples of metal ions other than zinc ions include magnesium (Mg) ions, calcium (Ca) ions, and strontium (Sr) ions. The phosphate contains at least zinc ions and may further contain at least one metal ion selected from the group consisting of magnesium ions, calcium ions, and strontium ions. The type of the phosphates disposed on at least a part of the surface of the first fluoride particles may be only one type or may be a combination of two or more types.

When the phosphate contains zinc ions, the proportion of the number of moles of zinc ions to the total number of moles of metal ions contained in the phosphate may be, for example, 60 mol % or more, preferably 80 mol % or more, and may be 100 mol % or less. When the phosphate contains metal ions other than zinc ions, the proportion of the number of moles of metal ions other than zinc ions to the total number of moles of metal ions contained in the phosphate may be, for example, 60 mol % or less, preferably 40 mol % or less, or 20 mol % or less, and may be 10 mol % or more. In one aspect, the phosphate may be substantially zinc phosphate. The term “substantially” is intended not to exclude metal ions other than zinc ions that are inevitably mixed. Specifically, it means that the proportion of the number of moles of metal ions other than zinc ions to the total number of moles of metal ions contained in the phosphate is 5 mol % or less, or 1 mol % or less.

The content percentage of the phosphate in the fluoride phosphor may be, for example, 0.01 mass % or more, preferably 0.1 mass % or more, or 0.2 mass % or more, and may be 5 mass % or less, or 2 mass % or less, in terms of zinc with respect to fluoride phosphor. When the content percentage of the phosphate is within the above-described range, the reliability of the light-emitting device tends to be more effectively improved. The content percentage of the phosphate in the fluoride phosphor can be calculated by inductively coupled plasma (ICP) emission spectrometry.

The fluoride phosphor may further contain an oxide disposed on at least a part of the surface of the first fluoride particles. The oxide may cover at least a part of the surface of the first fluoride particles. The oxide may be disposed directly on the surface of the first fluoride particles and cover the first fluoride particles, or may cover the first fluoride particles via a phosphate disposed on the surface of the first fluoride particles. The oxide may cover, for example, the surface of the first fluoride particles in a film shape, and may be disposed, as an oxide layer, on the surface of the first fluoride particles. The oxide film covering the surface of the first fluoride particles is not limited to a state in which no cracks are present, but cracks may partially be present in the oxide film covering the surface of the first fluoride particles as long as the effect of the present disclosure can be achieved. Although the oxide film covering the surface of the first fluoride particles preferably completely covers the entire surface thereof, a part of the oxide film may be partially missing, and the surface of the first fluoride particles may be partially exposed as long as the effect can be achieved. The coverage percentage of the fluoride particles by the oxide in the first fluoride phosphor may be, for example, 50% or more, preferably 80% or more, or 90% or more. The coverage percentage of the first fluoride particles by the oxide is calculated as the ratio of the surface area covered by the oxide to the surface area of the first fluoride particle.

The oxide may contain at least one element selected from the group consisting of silicon (Si), aluminum (Al), titanium (Ti), zirconium (Zr), tin (Sn), and zinc (Zn). That is, the oxide may include at least one selected from the group consisting of silicon oxides (for example, SiOx, where x may be in a range of 1 to 2, preferably from 1.5 to 2, or approximately 2), aluminum oxides (for example, Al₂O₃), titanium oxides (for example, TiO₂), zirconium oxides (for example, ZrO₂), tin oxides (for example, SnO and SnO₂), and zinc oxides (for example, ZnO), and may include at least a silicon oxide. Only a single type of oxide may be included, or two or more types may be included.

The content percentage of the oxide in the fluoride phosphor may be in a range of 2 mass % to 30 mass %, and preferably from 5 mass % to 20 mass %, or from 8 mass % to 15 mass %, with respect to the fluoride phosphor. Regarding the content percentage of the oxide in the fluoride phosphor, when the oxide is a silicon oxide for example, the amounts of each constituent element contained in the fluoride particles covered by the oxide and in the fluoride particles not containing the oxide are analyzed by inductively coupled plasma (ICP) emission spectrometry, and the molar ratios of the respective constituent elements are calculated such that the number of moles of the alkali metal is 2. The difference in the mole ratio of silicon before and after covering with the oxide is converted to the mass of silicon oxide (for example, SiO₂), and the content percentage of the silicon oxide (for example, SiO₂) is calculated with the mass of the first fluoride particles (fluoride phosphor) covered with the oxide being 100 mass %. The reliability of the light-emitting device can be further improved by setting the content percentage of the oxide to within the above-described range.

In the fluoride phosphor, the first fluoride particles may be covered with an oxide layer. The average thickness of the oxide layer covering the first fluoride particles may be, for example, in a range of 20 nm to 800 nm, preferably 100 nm or more, or 200 nm or more, and may be 700 nm or less, or 500 nm or less. The average thickness of the oxide layer in the first fluoride phosphor may be, for example, an actually measured average thickness determined by actually measuring the thickness of a layer identified as an oxide layer at several positions in a cross-sectional image of the fluoride phosphor and then calculating the arithmetic mean thereof. The average thickness of the oxide layer in the fluoride phosphor may be a below-described theoretical thickness calculated from the intensity ratio of Kα rays of the element F. The theoretical thickness can be calculated from a ratio of a peak intensity of Kα rays of the element F in the first fluoride phosphor covered with an oxide layer to a peak intensity of Kα rays of the element F in the first fluoride particles not covered with an oxide layer, using a database from The Center for X-Ray Optics (CXRO). The theoretical thickness is calculated as a value calculated by averaging presence of defects such as cracks and chippings in the oxide layer.

In the fluoride phosphor containing an oxide, the first fluoride particles are covered with an oxide, and thus the peak intensity of characteristic X-rays derived from the first fluoride particles decreases in accordance with the amount of the oxide covering the first fluoride particles. Thus, in the fluoride phosphor, the state of coverage by the oxide can be evaluated by evaluating the peak intensity of the characteristic X-rays derived from the first fluoride particles. Specifically, in X-ray fluorescence (XRF) elemental analysis, the ratio of the peak intensity of Kα rays of the element F in the fluoride phosphor to the peak intensity of the Kα rays of the element F in the first fluoride particles may be, for example, 80% or less, and is preferably 70% or less, or 60% or less. The lower limit value of the ratio of the peak intensities may be, for example, 20% or greater. The reliability of the light-emitting device can be more effectively improved by setting the ratio of the peak intensity of the Kα rays of the element F in the fluoride phosphor to within the above-described range.

The surface of the fluoride phosphor may be further treated with a coupling agent. That is, a surface treatment layer containing a functional group derived from a coupling agent may be disposed on the surface of the fluoride phosphor. By disposing the surface treatment layer on the surface of the fluoride phosphor, for example, the moisture resistance of the fluoride phosphor is further improved.

Examples of the functional group derived from the coupling agent include a silyl group having an aliphatic group with of 1 to 20 carbons, and preferably a silyl group having an aliphatic group with of 6 to 12 carbons. For the functional group derived from the coupling agent, only a single type may be used, or a combination of two or more types may be used.

Examples of the coupling agent include a silane coupling agent, a titanium coupling agent, and an aluminum coupling agent. Examples of the silane coupling agent include alkyl trialkoxysilanes, such as methyl trimethoxysilane, ethyl trimethoxysilane, propyl trimethoxysilane, hexyl trimethoxysilane, octyl trimethoxysilane, decyl trimethoxysilane, and decyl triethylsilane; aryl trialkoxysilanes, such as phenyl trimethoxysilane, and styryl trimethoxysilane; vinyl trialkoxysilanes, such as vinyl trimethoxysilane; aminoalkyl trialkoxysilanes, such as 3-aminopropyl triethoxysilane; and glycidoxyalkyl trialkoxysilanes, such as 3-glycidoxypropyl trimethoxysilane, and the silane coupling agent may be at least one selected from the group consisting of these. From the viewpoint of relative availability, the coupling agent is preferably a silane coupling agent.

From the viewpoint of improving luminance, a volume-based median size of the fluoride phosphor may be, for example, in a range of 10 μm to 90 μm, and is preferably in a range of 15 μm to 70 μm or of 20 μm to 50 μm. From the viewpoint of improving luminance, the particle size distribution of the fluoride phosphor may have a single peak, and preferably has a single peak with a narrow distribution range. Specifically, in the volume-based particle size distribution, the ratio of D90 to D10 (D90/D10) may be, for example, 3.0 or less.

The fluoride phosphor is, for example, a phosphor activated by a tetravalent manganese ion, and the fluoride phosphor absorbs light of a short wavelength range of visible light and emits red light. The excitation light may be primarily light in the blue region, and the peak wavelength of the excitation light may be, for example, within a wavelength range of 380 nm to 485 nm. The light emission peak wavelength in the emission spectrum of the fluoride phosphor may be, for example, within a wavelength range of 610 nm to 650 nm. The full width at half maximum in the emission spectrum of the fluoride phosphor may be, for example, 10 nm or less.

### Method for Manufacturing Fluoride Phosphor

The method for manufacturing a fluoride phosphor may include: a provision step of providing first fluoride particles having a specific composition; and a phosphate adhesion step of obtaining a second fluoride phosphor in which a phosphate is adhered to the first fluoride particles by bringing the first fluoride particles, a phosphate ion, and at least one metal ion selected from the group consisting of magnesium (Mg), calcium (Ca), strontium (Sr), and zinc (Zn) into contact with each other in a liquid medium. The method for manufacturing a fluoride phosphor may further include other steps, as necessary. The first fluoride particles may have a composition in which an element M, an alkali metal, manganese, and a fluorine atom are contained in its composition, the element M containing at least one selected from the group consisting of Group 4 elements, Group 13 elements, and Group 14 elements, and when the number of moles of the alkali metal is 2, the number of moles of manganese is in a range of more than 0 and less than 0.2, the number of moles of the element Mis in a range of more than 0.8 and less than 1, and the number of moles of the fluorine atom is in a range of more than 5 and less than 7.

By bringing a specific metal ion and a phosphate ion into contact with the first fluoride particles in a liquid medium, a metal phosphate containing a specific metal ion is precipitated in at least a partial region of the surface of the first fluoride particles, and a second fluoride phosphor in which the metal phosphate is adhered to the surface of the first fluoride particles can be obtained. A light-emitting device configured by using the resulting second fluoride particles can improve reliability in a high-temperature and high-humidity environment.

In the provision step, first fluoride particles having a predetermined composition are provided. In the provision step, provision may be achieved by purchasing or otherwise obtaining the first fluoride particles, or by manufacturing the desired first fluoride particles. The details of the first fluoride particles to be provided are as described above.

The first fluoride particles can be manufactured as follows, for example. In a case in which the first fluoride particles have the first composition, for example, the first fluoride particles having the first composition can be manufactured by a manufacturing method including mixing solution a and solution b. The solution a contains: at least hydrogen fluoride; a first complex ion including tetravalent manganese; and a second complex ion including a fluorine ion and at least one selected from the group consisting of Group 4 elements and Group 14 elements. The solution b contains at least hydrogen fluoride and an alkali metal including at least potassium.

The fluoride particles can also be manufactured by a manufacturing method including a step of mixing a first solution, a second solution, and a third solution, the first solution containing at least hydrogen fluoride and a first complex ion including tetravalent manganese, the second solution containing at least hydrogen fluoride and an alkali metal including at least potassium, and the third solution containing at least a second complex ion including a fluorine ion and at least one selected from the group consisting of Group 4 elements and Group 14 elements. For the method for manufacturing the first fluoride particles having the first composition, for example, reference can be made to Japanese Patent Publication No. 2015-044973.

In a case in which the first fluoride particles have the second composition, the first fluoride particles having the second composition can be manufactured by, for example, a manufacturing method including providing fluoride particles having the first composition; providing a composite fluoride containing Al, an alkali metal, and F; and performing a first heat treatment step of subjecting a mixture of the composite fluoride and the fluoride particles containing the first composition to a first heat treatment in an inert gas atmosphere at a first heat treatment temperature in a range of 600° C. to 780° C. Here, the composition of the composite fluoride containing Al, an alkali metal, and F may be such that the ratio of the total number of moles of the alkali metal per mole of Al is in a range of 1 to 3, and the ratio of the number of moles of F per mole of Al is in a range of 4 to 6. Alternatively, the ratio of the total number of moles of the alkali metal per mole of Al may be in a range of 2 to 3, and the ratio of the number of moles of F per mole of Al may be in a range of 5 to 6.

The method for manufacturing the first fluoride particles may further include a second heat treatment step in which, subsequent to the first heat treatment, the obtained first heat-treated product is subjected to a second heat treatment at a second heat treatment temperature of 400° C. or more to obtain a second heat-treated product.

The second heat treatment step may be performed using only the first fluoride particles obtained by the first heat treatment, or may be performed by bringing the first fluoride particles into contact with a fluorine-containing substance. The fluorine-containing substance may be in a solid state, a liquid state, or a gaseous state at normal temperature. An example of a fluorine-containing substance that is in a solid or liquid state is NH₄F. Also, examples of fluorine-containing substances that are in a gaseous state include F₂, CHF₃, CF₄, NH₄HF₂, HF, SiF₄, KrF₄, XeF₂, XeF₄, and NF₃. The fluorine-containing substance that is in a gaseous state may be at least one selected from the group consisting of these, and is preferably at least one selected from the group consisting of F₂ and HF.

The second heat treatment temperature is preferably higher than 400° C., and may be 425° C. or higher, 450° C. or higher, or 480° C. or higher. The upper limit of the second heat treatment temperature may be, for example, less than 600° C., preferably 580° C. or lower, such as 550° C. or lower or 520° C. or lower. The second heat treatment temperature may be a temperature lower than the first heat treatment temperature.

It is assumed that the first fluoride particles having the second composition synthesized by the solid-phase reaction method in the first heat treatment step are in a state of containing a compound having a so-called mixed valence because tetravalent Si ions, trivalent Al ions, and tetravalent Mn ions are present at the same positions in the crystals of the first fluoride particles. Thus, it is assumed that vacancies exist at positions where fluorine ions should exist in the crystal in proportion to the abundance ratio of the tetravalent Si ions, the trivalent Al ions, and the tetravalent Mn ions in order to compensate for the deficient charge of all cations having mixed valences.

Here, as disclosed in Japanese Patent Publication No. 2010-254933 for example, in the first fluoride particles synthesized by the liquid-phase reaction method, a large number of hydroxide ions introduced into the crystal from the hydroxide ions present in the solution are present in a mixed manner with fluorine ions at positions where fluorine ions should be present in the crystals, and it is assumed that the hydroxide ions cause a loss of stability of the first fluoride particles. Meanwhile, a solution in which hydroxide ions can be present is not used in the first fluoride particles having the second composition synthesized by the solid-phase reaction method through heat treatment, and thus hydroxide ions that cause a loss of stability of the first fluoride particles are not present in a mixed manner.

In addition, in the first fluoride particles having the second composition and synthesized by the solid-phase reaction method through the first heat treatment, Mn ions having different valences are present in a mixed manner in the crystals or on the crystal surfaces of the fluoride particles. In a case in which Mn ions having different valences are present in a mixed manner in the fluoride particles, the valences of the Mn ions can be uniformly set to a tetravalent state by further subjecting to a heat treatment in a state in which the fluoride particles are in contact with a fluorine-containing substance, and thus the luminous efficiency of the first fluoride particles can be increased. For the method for manufacturing the first fluoride particles having the second composition, for example, reference can be made to Japanese Patent Publication No. 2022-099232.

The provision step may further include a modification step of forming a surface region having a manganese concentration lower than the manganese concentration in the inner region in the first fluoride particles. When the first fluoride particles have a surface region with a low manganese concentration, the generation of manganese dioxide on the particle surface is suppressed, and the decrease in light emission output and the chromaticity shift are suppressed over a long period of time. Thus, the reliability of a light-emitting device is further improved.

The modification step may include a reduction step that is bringing the first fluoride particles into contact with a reducing agent, and a surface region forming step that is bringing the first fluoride particles brought into contact with the reducing agent into contact with a second complex ion and a cation, in the presence of hydrogen fluoride. The second complex ion contains a fluorine ion and at least one selected from the group consisting of Group 4 elements and Group 14 elements. The cation contains an alkali metal containing at least potassium. Examples of the reducing agent include hydrogen peroxide and oxalic acid. For the method for manufacturing the first fluoride particles having a surface region having a manganese concentration lower than the manganese concentration in the inner region, reference can be made to Japanese Patent Publication No. 2023-058411.

The provision step may further include a pressure heating step that is subjecting the first fluoride particles to pressurization and heating treatment in a liquid medium. By subjecting the fluoride particles to pressurization and heating treatment in a liquid medium, first fluoride particles exhibiting good light emission luminance and durability can be obtained. In the first fluoride particles obtained through pressurization and heating treatment, for example, the reflectance at a wavelength of 510 nm increases, and for example, when the first fluoride particles are applied to lighting applications together with a green light-emitting phosphor, a decrease in luminance in the green region can be more effectively suppressed.

In the pressure heating step, a mixture containing the first fluoride particles and the liquid medium is subjected to pressurization and heating treatment. By performing the treatment in the liquid medium, the treatment effect on the first fluoride particles can be more uniformly imparted. The configuration of the liquid medium is not particularly limited, and can be appropriately selected from generally used liquids according to the purpose or the like. Specific examples of the liquid medium include water; and organic solvents, for example alcohol solvents such as methanol, ethanol, and isopropyl alcohol, ketone solvents such as acetone and methyl ethyl ketone, and ether solvents such as diethyl ether and diisopropyl ether. The liquid medium may be a substance that is a gas at normal pressure but is liquefied through pressurization, or a substance that is a solid at normal temperature but is liquefied through heating. The liquid medium preferably contains at least water. For the liquid medium, only a single type may be used, or a combination of two or more types may be used.

The liquid medium may further contain a component that is soluble in the liquid medium. Examples of the component soluble in the liquid medium include inorganic acids, such as hydrogen fluoride (HF), hexafluorosilicic acid (H₂SiF₆), and nitric acid (HNO₃); peroxides such as hydrogen peroxide; and inorganic acid salts containing potassium ions, such as potassium hydrogen fluoride (KHF₂), potassium nitrate (KNO₃), and potassium fluoride (KF). Of these, the liquid medium preferably contains at least potassium ions, and more preferably contains at least an inorganic acid salt containing potassium ions. When the liquid medium contains potassium ions, the concentration of potassium ions can be, for example, in a range of 5 mass % to 10 mass %. For the component soluble in the liquid medium, only a single type may be used, or a combination of two or more types may be used.

The amount of use of the liquid medium is not particularly limited, and can be appropriately selected according to a treatment method or the like. The amount of use of the liquid medium may be, for example, in a range of 100 parts by mass to 160 parts by mass, and preferably in a range of 130 parts by mass to 160 parts by mass with respect to 100 parts by mass of the first fluoride particles.

From the viewpoint of improving durability, the pressure condition of the pressurization treatment may be, for example, 1.5 MPa or more, preferably 2.5 MPa or more, or 5.0 MPa or more according to calculations. From the viewpoint of durability and production efficiency, the pressure condition may be, for example, 30 MPa or less, and preferably 15 MPa or less. The time of the pressurization treatment may be appropriately selected according to the treatment conditions such as the pressure. From the viewpoint of improving durability, the treatment time may be, for example, 4 hours or more, preferably 6 hours or more, or 8 hours or more. From the viewpoints of durability and production efficiency, the treatment time may be, for example, 48 hours or less, preferably 24 hours or less, or 20 hours or less.

In the pressurization treatment, for example, the mixture may be placing into a pressure-resistant airtight container such as an autoclave and pressurized. The pressurizing method may be appropriately selected from generally used pressurizing methods without particular limitation. Specifically, for example, the pressurization treatment may be performed by reducing the volume of a pressure-resistant airtight container, by injecting a gas such as air or an inert gas, or by using pressure resulting from the vapor pressure of the liquid medium or the like when the heating treatment is performed while maintaining an airtight state. The atmosphere in the pressurization treatment may be an air atmosphere or an inert gas atmosphere without particular limitation.

From the viewpoint of improving durability, the temperature of the heating treatment may be, for example, 100° C. or more, preferably 120° C. or more, or 150° C. or more. From the viewpoints of durability and production efficiency, the temperature of the heating treatment may be, for example, 300° C. or less, and preferably 200° C. or less. The time of the heating treatment may be appropriately selected according to treatment conditions such as the temperature. From the viewpoint of durability, the heating treatment time may be, for example, 4 hours or more, and preferably 8 hours or more. From the viewpoints of durability and production efficiency, the heating treatment time may be, for example, 24 hours or less, preferably 20 hours or less. The atmosphere in the heating treatment may be an air atmosphere or an inert gas atmosphere without particular limitation.

In the pressure heating step, the pressurization treatment and the heating treatment may be performed sequentially, or each treatment may be performed in a temporally overlapping manner. When the pressurization treatment and the heating treatment are implemented in a temporally overlapping manner, for example, the pressurization treatment can be performed using the vapor pressure of the liquid medium by placing the mixture into a pressure-resistant airtight container and then implementing the heating treatment. In the pressure heating treatment step, treatment is preferably performed at a heating temperature in a range of 120° C. to 300° C. and a pressure in a range of 2.5 MPa to 30 MPa for a time in a range of 8 hours to and 48 hours, and more preferably performed at a temperature in a range of 150° C. to 200° C. and a pressure in a range of 5.0 MPa to 12 MPa for a time in a range of 6 hours to 24 hours. For the pressure heating step for the first fluoride particles, for example, reference can be made to the description of Japanese Patent Publication No. 2015-199877.

The provision step may further include additional steps such as a step of recovering the resulting first fluoride phosphor through solid-liquid separation, and a step of drying the solid-liquid separated fluoride phosphor.

In the phosphate adhesion step, the provided first fluoride particles, at least one metal ion selected from the group consisting of magnesium (Mg), calcium (Ca), strontium (Sr), and zinc (Zn), and phosphate ions are brought into contact with each other in a liquid medium. Through this, a phosphate containing a specific metal ion is adhered to the surface of the fluoride particles, and the second fluoride particles to which the metal phosphate is adhered are obtained. It is assumed that by adhering a metal phosphate to the first fluoride particles in a liquid medium, the metal phosphate is adhered more uniformly to the surface of the first fluoride particles, for example.

The liquid medium is not limited as long as it can dissolve the phosphate ions and the metal ions, and preferably contains at least water from the viewpoint of easily dissolving these ions. As necessary, the liquid medium may further include a reducing agent such as hydrogen peroxide, an organic solvent, a pH adjusting agent, or the like. Examples of the organic solvent that can be contained in the liquid medium include alcohol solvents such as ethanol and isopropanol. Examples of the pH adjusting agent include basic compounds such as ammonia, sodium hydroxide, and potassium hydroxide, and acidic compounds such as hydrochloric acid, nitric acid, sulfuric acid, and acetic acid. When the liquid medium contains a pH adjusting agent, the pH of the liquid medium may be, for example, in a range of 3 to 9, preferably in a range of 4 to 8, or in a range of 5 to 7. When the pH is equal to or more than the lower limit value described above, a sufficient adherence amount of the metal phosphate tends to be produced, and when the pH is equal to or less than the upper limit value described above, a decrease in the emission characteristics of the second fluoride phosphor tends to be suppressed. The pH is measured at 2° C. When the liquid medium contains water, the content percentage of the water in the liquid medium may be, for example, 70 mass % or greater, 80 mass % or greater, and preferably 90 mass % or greater.

The mass ratio of the liquid medium to the first fluoride particles is, for example, 100 mass % or more or 200 mass % or more and is, for example, 1000 mass % or less or 800 mass % or less. When the mass ratio of the liquid medium is equal to or more than the above-described lower limit value, more uniform adherence of the metal phosphate to the surfaces of the first fluoride particles is facilitated, and when the mass ratio of the liquid medium is equal to or less than the above-described upper limit value, the adherence rate of the metal phosphate to the first fluoride particles tends to further improve.

The liquid medium preferably contains phosphate ions, and more preferably contains water and phosphate ions. In a case in which the liquid medium contains phosphate ions, the provided first fluoride particles and the liquid medium are mixed, and then further mixed with a solution containing specific metal ions, whereby the phosphate ions and the metal ions can be brought into contact in the liquid medium containing the first fluoride particles. In a case in which the liquid medium contains phosphate ions, the phosphate ion concentration in the liquid medium is, for example, 0.05 mass % or higher, preferably 0.1 mass % or higher, and, for example, 5 mass % or lower, and preferably 3 mass % or lower. When the phosphate ion concentration in the liquid medium is equal to or more than the lower limit value described above, the amount of the liquid medium is not excessive, elution of the composition components from the first fluoride particles is suppressed, and the characteristics of the second fluoride phosphor tend to be favorably maintained. When the phosphate ion concentration is equal to or less than the upper limit value described above, uniformity of matter adhered on the first fluoride particles tends to be favorable.

Phosphate ions include ortho-phosphate ions, polyphosphate (meta-phosphate) ions, phosphite ions, and hypophosphite ions. Polyphosphate ions include polyphosphate ions having a linear structure, such as pyrophosphate ions and tripolyphosphate ions, and cyclic polyphosphate ions, such as hexa-meta-phosphate ions.

In a case in which the liquid medium contains phosphate ions, a compound that serves as a source of phosphate ions may be dissolved in the liquid medium to provide the liquid medium containing phosphate ions, or a solution containing a phosphate ion source may be mixed with the liquid medium to provide the liquid medium containing phosphate ions. Examples of the phosphate ion source include: phosphoric acid; meta-phosphoric acid; alkali metal phosphates such as sodium phosphate and potassium phosphate; alkali metal hydrogen phosphates such as sodium hydrogen phosphate and potassium hydrogen phosphate; alkali metal dihydrogen phosphates such as sodium dihydrogen phosphate and potassium dihydrogen phosphate; alkali metal hexa-meta-phosphates such as sodium hexa-meta-phosphate and potassium hexa-meta-phosphate; alkali metal pyrophosphates such as sodium pyrophosphate and potassium pyrophosphate; and ammonium phosphates such as ammonium phosphate.

The liquid medium may contain a reducing agent, preferably contains water and a reducing agent, and more preferably contains water, phosphate ions, and a reducing agent. By containing a reducing agent in the liquid medium, precipitation of manganese dioxide or the like derived from manganese contained in the first fluoride particles can be effectively suppressed. The reducing agent contained in the liquid medium is not limited as long as it reduces, for example, tetravalent manganese ions eluted from the first fluoride particles into the liquid medium. Examples of the reducing agent include hydrogen peroxide, oxalic acid, and hydroxylamine hydrochloride. Among them, hydrogen peroxide decomposes in water and thus does not adversely affect the second fluoride particles, which is preferable.

In a case in which the liquid medium contains a reducing agent, a compound that serves as a reducing agent may be dissolved in the liquid medium to provide the liquid medium containing a reducing agent, or a solution containing a reducing agent may be mixed with the liquid medium to provide the liquid medium containing a reducing agent. The content of the reducing agent in the liquid medium is not particularly limited, but for example, the content may be 0.1 mass % or higher, and preferably 0.3 mass % or higher.

A metal element for bringing into contact with a phosphate ion to be a metal ion is preferably at least one selected from the group consisting of magnesium (Mg), calcium (Ca), strontium (Sr), and zinc (Zn), and more preferably contains at least zinc. The proportion of the number of moles of zinc ions to the total number of moles of metal ions to be brought into contact with phosphate ions may be, for example, 40 mol % or more, preferably 60 mol % or more, or 80 mol % or more, and may be 100 mol % or less, or 90 mol % or less. When the metal ions to be brought into contact with the phosphate ions include metal ions other than zinc ions, the proportion of the number of moles of the metal ions other than zinc ions to the total number of moles of the metal ions may be, for example, 60 mol % or less, preferably 40 mol % or less, or 20 mol % or less, and may be 10 mol % or more.

The contact between the phosphate ions and the metal ions in the liquid medium may be caused, for example by dissolving a compound that serves as a metal ion source in a liquid medium containing phosphate ions, or by mixing a liquid medium containing phosphate ions with a solution containing metal ions. The solution containing metal ions can be provided, for example, by dissolving a compound that serves as a metal ion source in a solvent such as water. The compound that serves as a metal ion source is, for example, a metal salt containing a specific metal element, and examples of the anion constituting the metal salt include nitrate ions, sulfate ions, acetate ions, and chloride ions.

The contact between the phosphate ions and the metal ions in the liquid medium can include, for example, obtaining a phosphor slurry by mixing first fluoride particles with a liquid medium containing phosphate ions and preferably further containing a reducing agent, and mixing the phosphor slurry with a solution containing metal ions. The phosphor slurry and the solution containing metal ions may be mixed by adding the solution containing metal ions to the phosphor slurry. The time required for adding the solution containing metal ions may be, for example, in a range of 30 seconds to 4 hours, and preferably in a range of 1 hour or more and 3 hours or less. When a solution containing metal ions is added to the phosphor slurry, the pH of the phosphor slurry may change with the addition of the solution containing metal ions. The change in the pH may be, for example, a change in which the pH decreases. The pH changing range may be, for example, in a range of 3 to 9, and preferably in a range of 5 to 7.

The content percentage of metal ions in the solution containing metal ions may be, for example, 0.05 mass % or more or 0.1 mass % or more, and may be, for example, 3 mass % or less or 2 mass % or less. The content percentage of the metal ions with respect to the amount of fluoride particles in the liquid medium may be, for example, 0.2 mass % or more or 0.5 mass % or more, and it may be, for example, 30 mass % or less or 20 mass % or less. When the content percentage of the metal ions is equal to or more than the lower limit value described above, the adherence rate of the metal phosphate to the first fluoride particles tends to be further improved. When the concentration of the metal ions is equal to or less than the upper limit value described above, the metal phosphate tends to be easily adhered more uniformly to the surfaces of the first fluoride particles.

The ratio of the total number of moles of metal ions contained in the solution containing metal ions to the total number of moles of phosphate ions contained in the liquid medium based on the phosphorus atom may be, for example, in a range of 0.01 to 5, and may be preferably 0.1 or more, or 0.5 or more, and preferably 3 or less, or 1.5 or less.

The contact temperature between the phosphate ion and the metal ion forming the metal phosphate may be, for example, in a range of 0° C. to 50° C., and preferably 35° C. or less, 20° C. or less, 10° C. or less, or 5° C. or less. When the contact temperature is within the above-described range, the adhesion of the metal phosphate to the surface of the first fluoride particles tends to be more uniform. The contact time may be, for example, in a range of 1 minute to 4 hours, and preferably in a range of 10 minutes to 3 hours. The contact may be caused while stirring of the liquid medium is performed. The contact time includes a time required for adding the solution containing metal ions.

After the adhesion step, a separation step may be provided in which the second fluoride particles to which the metal phosphate is adhered are separated from the liquid medium. The separation can be caused by, for example, a solid-liquid separation means such as filtration or centrifugal separation. The second fluoride particles obtained by solid-liquid separation may be subjected to a washing treatment, a drying treatment, or the like as necessary.

A metal phosphate is disposed on the surface of the second fluoride particles obtained in the adhesion step. The shape of the metal phosphate to be disposed may be, for example, a particle shape. The shape of the phosphate in a particle shape may be, for example, a rod shape, a needle shape, or the like. The percentage of the surface of the second fluoride particles covered by the metal phosphate may be, for example, 50% or more, preferably 80% or more, or 90% or more.

The method for manufacturing a fluoride phosphor may further include an alkali treatment step of bringing the second fluoride particles obtained in the adhesion step into contact with an alkaline liquid medium to obtain third fluoride particles. By subjecting the second fluoride particles to which the metal phosphate is adhered to an alkali treatment, the third fluoride particles in which the metal phosphate is more uniformly disposed can be obtained.

The liquid medium in the alkali treatment step is not limited as long as it contains water and an alkaline substance. The liquid medium may further include a reducing agent such as hydrogen peroxide, an organic solvent, or the like, as necessary. Examples of the organic solvent that can be contained in the liquid medium include organic solvents, including alcohol solvents such as ethanol and isopropanol, ketone solvents such as acetone and methyl ethyl ketone, and ether solvents such as diethyl ether and diisopropyl ether. When the liquid medium contains an organic solvent, the content percentage of the organic solvent in the liquid medium may be, for example, in a range of 50 vol % to 99 vol %, and preferably in a range of 80 vol % to 95 vol %. When the liquid medium contains a reducing agent, the content percentage of the reducing agent in the liquid medium may be, for example, in a range of 0.5 mass % to 10 mass %, and preferably in a range of 2 mass % to 5 mass %.

Examples of the alkaline substance contained in the liquid medium include basic compounds such as ammonia, sodium hydroxide, and potassium hydroxide. The pH of the liquid medium may be, for example, in a range of 8 to 13, preferably 9 or more, or 10 or more, and may be 12 or less, or 11 or less. When the pH of the liquid medium is within the above-described range, zinc phosphate dissolves and tends to form a film. The pH of the liquid medium is measured at 25° C.

The contact temperature between the second fluoride particles and the alkaline liquid medium may be, for example, in a range of 10° C. to 50° C., and preferably in a range of 20° C. to 35° C. The contact time may be, for example, in a range of 1 minute to 4 hours, and preferably in a range of 60 minutes to 3 hours. The contact may be caused while stirring the liquid medium.

After the alkali treatment step, a separation step of separating the third fluoride particles and the liquid medium may be provided. The separation can be caused by, for example, a solid-liquid separation means such as filtration or centrifugal separation. The third fluoride particles obtained by solid-liquid separation may be subjected to a washing treatment, a drying treatment, or the like, as necessary.

A metal phosphate is disposed on the surface of the third fluoride particles obtained in the alkali treatment step. The shape of the metal phosphate to be disposed may be, for example, a film shape. The percentage of the surface of the third fluoride particles covered with the metal phosphate may be, for example, 50% or more, and preferably 80% or more, or 90% or more.

The method for manufacturing a fluoride phosphor may further include an oxide covering step of bringing the second fluoride particles obtained in the adhesion step or the third fluoride particles obtained in the alkali treatment step into contact with a metal alkoxide containing at least one selected from the group consisting of silicon (Si), aluminum (Al), titanium (Ti), zirconium (Zr), tin (Sn), and zinc (Zn) in a liquid medium to obtain fourth fluoride particles in which an oxide derived from the metal alkoxide is disposed on at least a part of the surface of the second fluoride particles or the third fluoride particles. In a light-emitting device including a fluorescent member containing the resulting fourth fluoride particles and resin, for example, reliability in a high-temperature and high-humidity environment is further improved.

In the oxide covering step, the provided second fluoride particles or third fluoride particles (hereinafter, also collectively referred to as “phosphate-adhered fluoride particles”) are brought into contact with a metal alkoxide containing at least one selected from the group consisting of silicon, aluminum, titanium, zirconium, tin, and zinc in a liquid medium, and the phosphate-adhered fluoride particles are covered with an oxide derived from the metal alkoxide to obtain a fourth fluoride phosphor. An oxide derived from the metal alkoxide can be produced by solvolysis of the metal alkoxide, and a fluoride phosphor containing the fourth fluoride particles covered by the produced oxide is obtained.

An aliphatic group of the alkoxide constituting the metal alkoxide may have a number of carbons, for example, in a range of 1 to 6, preferably from 1 to 4, or from 1 to 3. The metal alkoxide contains at least one selected from the group consisting of silicon, aluminum, titanium, zirconium, tin, and zinc, but it may contain at least silicon. For each of the metal and the aliphatic group contained in the metal alkoxide, only a single type may be used alone, or two or more types may be used in combination.

Specific examples of the metal alkoxide include tetramethoxysilane, tetraethoxysilane, tetraisopropoxysilane, trimethoxy aluminum, triethoxy aluminum, triisopropoxy aluminum, tetramethoxy titanium, tetraethoxy titanium, tetraisopropoxy titanium, tetramethoxy zirconium, tetraethoxy zirconium, tetraisopropoxy zirconium, tetraethoxy tin, dimethoxy zinc, and diethoxy zinc. The metal alkoxide may include at least one selected from the group consisting of these, and may be preferably at least one selected from the group consisting of tetramethoxysilane, tetraethoxysilane, and tetraisopropoxysilane. For the metal alkoxide in the oxide covering step, only a single type may be used, or a combination of two or more types may be used.

The addition amount of the metal alkoxide used in the oxide covering step may be, for example, in a range of 0.3 mass % to 30 mass %, preferably 1 mass % or more, or 3 mass % or more, and preferably 25 mass % or less, or 20 mass % or less with respect to the total mass of the phosphate-adhered fluoride particles as an addition amount in terms of oxide. The addition amount of the metal alkoxide used in the oxide covering step may be, for example, in a range of 0.5 mass % to 110 mass %, and preferably 2 mass % or more or 5 mass % or more, and preferably 90 mass % or less or 75 mass % or less, with respect to the total mass of the fluoride particles.

The contact between the phosphate-adhered fluoride particles and the metal alkoxide is performed in a liquid medium. Examples of the liquid medium include water; alcohol solvents such as methanol, ethanol, and isopropyl alcohol; nitrile solvents such as acetonitrile; and hydrocarbon-based solvents such as hexane. The liquid medium may contain at least water and an alcohol solvent. When the liquid medium contains an alcohol solvent, the content percentage of the alcohol-based solvent in the liquid medium may be, for example, 60 mass % or more, and preferably 70 mass % or more. The content of water in the liquid medium may be, for example, in a range of 4 mass % to 40 mass %.

The liquid medium may further contain a pH adjusting agent. Examples of the pH adjusting agent include an alkaline substance such as ammonia, sodium hydroxide, and potassium hydroxide, and an acidic substance such as hydrochloric acid, nitric acid, sulfuric acid, and acetic acid. When the liquid medium contains a pH adjusting agent, in acidic conditions, the pH of the liquid medium may be, for example, in a range of 1 to 6, and preferably from 2 to 5. In alkaline conditions, the pH of the liquid medium may be in a range of 8 to 12, and preferably from 8 to 11.

The mass ratio of the liquid medium to the phosphate-adhered fluoride particles may be, for example, 100 mass % or more, 1000 mass % or less, preferably 150 mass % or more, or 180 mass % or more, and preferably 600 mass % or less, or 300 mass % or less. When the mass ratio of the liquid medium is within the range described above, the fluoride particles tend to be more uniformly covered with oxides.

The contact between the phosphate-adhered fluoride particles and the metal alkoxide can be performed, for example, by adding the metal alkoxide to a suspension containing the phosphate-adhered fluoride particles. As necessary, stirring or the like may be performed at that time. The contact temperature of the fluoride particles and the metal alkoxide may be, for example, in a range of 0° C. to 70° C., and preferably from 10° C. to 40° C. The contact time may be, for example, in a range of 1 hour to 12 hours. The time required for the addition of the metal alkoxide is also included in the contact time.

After the oxide covering step, a separation step of separating the fourth fluoride particles and the liquid medium may be provided. The separation can be caused by, for example, a solid-liquid separation means such as filtration or centrifugal separation. The fourth fluoride particles obtained by solid-liquid separation may be subjected to a washing treatment, a drying treatment, or the like, as necessary.

The method for manufacturing a fluoride phosphor may include a surface treatment step in which the fluoride phosphor obtained in the synthesizing step is treated with a coupling agent. The manufacturing method may further include performing a silane coupling treatment after the fluoride particles have been covered with the oxide derived from the metal alkoxide. In the surface treatment step, the fluoride phosphor and a coupling agent are brought into contact, and thereby a surface treatment layer including a functional group derived from the coupling agent can be provided on the surface of the fluoride phosphor. Through this, for example, moisture resistance of the fluoride phosphor is improved.

Specific examples of the coupling agent used in the surface treatment step are as described above. The amount of the coupling agent used in the surface treatment step may be, for example, in a range of 0.5 mass % to 10 mass %, and preferably in a range of 1 mass % to 5 mass %, with respect to the content of the fluoride phosphor. The contact temperature between the fluoride phosphor and the coupling agent may be, for example, in a range of 0° C. to 70° C., and preferably from 10° C. to 40° C. The contact time between the fluoride phosphor and the coupling agent may be, for example, in a range of 1 minute to 10 hours, and preferably from 10 minutes to 1 hour.

### Light-Emitting Device

The light-emitting device includes: a wavelength conversion member containing a resin and a first phosphor containing the fluoride phosphor; and a light-emitting element having a light emission peak wavelength in a wavelength range of 380 nm to 485 nm. The light-emitting device may further include other constituent members, as necessary.

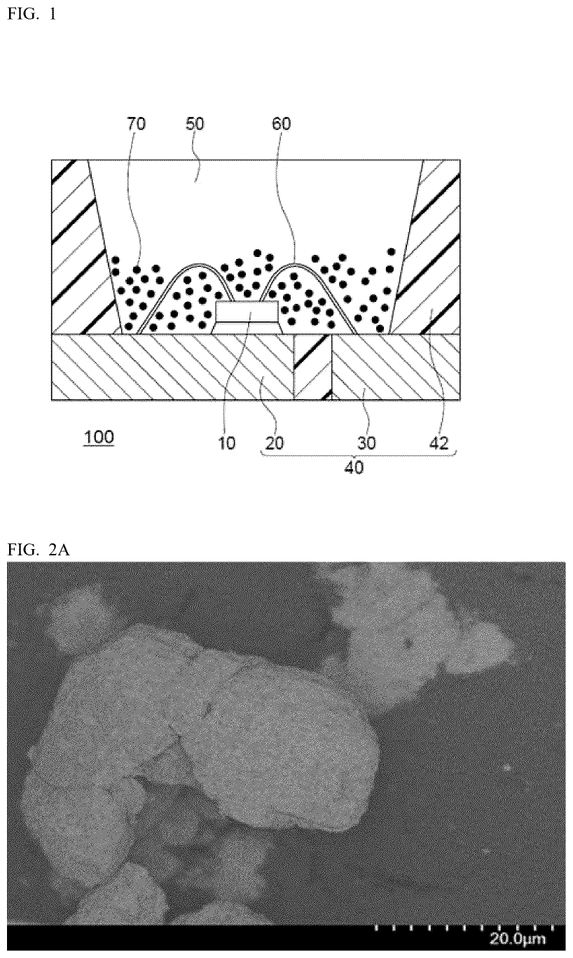

An example of the light-emitting device will be described with reference to the drawings. FIG. 1 is a schematic cross-sectional view illustrating one example of a light-emitting device according to the present embodiment. This light-emitting device is an example of a surface-mounted light-emitting device. A light-emitting device 100 includes a light-emitting element 10 that emits light having a light emission peak wavelength on the short-wavelength side of visible light (for example, in a range of 380 nm to 485 nm), and a molded body 40 on which the light-emitting element 10 is mounted. The molded body 40 has a first lead 20 and a second lead 30, and is integrally molded using a thermoplastic resin or a thermosetting resin. A recessed portion having a bottom surface and side surfaces is formed in the molded body 40, and the light-emitting element 10 is placed on the bottom surface of the recessed portion. The light-emitting element 10 includes a pair of positive and negative electrodes, and the pair of the positive and negative electrodes are electrically connected to the first lead 20 and the second lead 30 via wires 60. The light-emitting element 10 is sealed by a wavelength conversion member 50. The wavelength conversion member 50 contains a phosphor 70 including a fluoride phosphor that converts the wavelength of light from the light-emitting element 10. The phosphor 70 may contain the first phosphor including the fluoride phosphor, and a light-emitting material which, in response to excitation light from the light-emitting element 10, emits light having a light emission peak wavelength in a wavelength range different from that of the fluoride phosphor.

The wavelength conversion member may contain a resin and a phosphor. Examples of the resin constituting the wavelength conversion member include a silicone resin, an epoxy resin, a modified silicone resin, a modified epoxy resin, and an acrylic resin. For example, the refractive index of a silicone resin may be in a range of 1.35 to 1.55, and is more preferably in a range of 1.38 to 1.43. When the refractive index of the silicone resin is within these ranges, the silicone resin has excellent transmissivity and can be suitably used as a resin constituting the wavelength conversion member. The refractive index of the silicone resin is the refractive index after curing, and is measured in accordance with JIS K 7142:2008. The wavelength conversion member may further include a light-diffusing material in addition to the resin and the phosphor. When a light-diffusing material is included, directivity from the light-emitting element can be alleviated, and a viewing angle can be increased. Examples of the light-diffusing material include silicon oxide, titanium oxide, zinc oxide, zirconium oxide, and aluminum oxide.

The light-emitting element emits light having a light emission peak wavelength in a wavelength range of 380 nm to 485 nm, which is a short wavelength range of visible light. The light-emitting element may be an excitation light source that excites a fluoride phosphor. The light-emitting element preferably has a light emission peak wavelength within a range of 380 nm to 480 nm, more preferably has a light emission peak wavelength within a range of 410 nm to 480 nm, and even more preferably has a light emission peak wavelength within a range of 430 nm to 480 nm. A semiconductor light-emitting element is preferably used as the light-emitting element of the excitation light source. A semiconductor light-emitting element used as an excitation light source enables a stable light-emitting device that exhibits high efficiency and high output linearity with respect to an input and that is strong against mechanical impact. As the semiconductor light-emitting element, for example, a semiconductor light-emitting element that uses a nitride-based semiconductor can be used. The full width at half maximum of the emission peak in the emission spectrum of the light-emitting element is preferably 30 nm or less, for example.

The light-emitting device includes a first phosphor including a fluoride phosphor. Details of the fluoride phosphor included in the light-emitting device are described above. The fluoride phosphor is contained, for example, in the wavelength conversion member covering the excitation light source. In the light-emitting device in which the excitation light source is covered with the wavelength conversion member containing the fluoride phosphor, part of the light emitted from the excitation light source is absorbed by the fluoride phosphor and emitted as red light. When an excitation light source that emits light having a light emission peak wavelength in the range of 380 nm to 485 nm is used, the emitted light can be utilized more effectively, loss of light emitted from the light-emitting device can be reduced, and a highly efficient light-emitting device can be provided.

The light-emitting device preferably further includes, in addition to the first phosphor containing the fluoride phosphor, a light-emitting material (hereinafter may be referred to as second phosphor) other than the fluoride phosphor. The light-emitting material other than the fluoride phosphor may be any material that absorbs light from the light source and converts the light into light having a wavelength different from that of the fluoride phosphor. Like the first phosphor, for example, the light-emitting material can be contained in a wavelength conversion member.

The light-emitting material may have a light emission peak wavelength in a wavelength range of 495 nm to 590 nm, and may preferably be at least one material selected from the group consisting of a β-sialon phosphor, a halosilicate phosphor, a silicate phosphor, a rare earth-aluminate phosphor, and a nitride phosphor. The β-sialon phosphor may have a composition represented by Formula (IIa), for example. The halosilicate phosphor may have a composition represented by Formula (IIb), for example. The silicate phosphor may have a composition represented by Formula (IIc), for example. The rare earth-aluminate phosphor may have a composition represented by Formula (IId). The nitride phosphor may have a composition represented by Formula (IIe), (IIf), or (IIg), for example. When the wavelength conversion member contains a β-sialon phosphor or a perovskite-based light-emitting material as the light-emitting material other than the fluoride phosphor, a light-emitting device that is used as, for example, a light source for a backlight can have a wider range of color reproducibility. When the wavelength conversion member contains, as the second phosphor other than the fluoride phosphor, a halosilicate phosphor, a silicate phosphor, a rare earth-aluminate phosphor, or a nitride phosphor, a light-emitting device can be obtained with higher color rendering properties or higher luminous efficiency when the light-emitting device is used as, for example, a lighting light source.

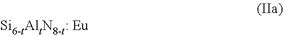

where in Formula (IIa), t satisfies 0<t≤4.2

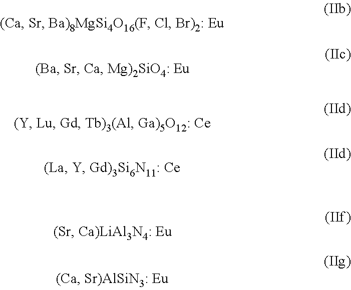

The average particle size of the light-emitting material is, for example, in a range of 0.1 μm to 7 μm, and is preferably 0.2 μm or more, or 0.5 μm or more. The average particle size is preferably 5 μm or smaller, or 3 μm or smaller. The average particle size of the light-emitting material is measured by the Fischer sub sieve sizer (FSSS) method. The wavelength conversion member may include only a single type of light-emitting material, or may include a combination of two or more types.

The wavelength conversion member may further contain at least one type of quantum dots in addition to the first phosphor. The quantum dots may be quantum dots that absorb light from the light source and convert the light to light of a wavelength differing from that of the first phosphor, or may be quantum dots that convert the absorbed light to light of approximately the same wavelength. Examples of quantum dots include quantum dots having a perovskite structure with a composition such as (Cs, FA, MA)(Pb, Sn)(Cl, Br, I)₃ (where FA denotes formamidinium and MA denotes methylammonium), quantum dots having a chalcopyrite structure with a composition such as (Ag, Cu, Au)(In, Ga)(S, Se, Te)₂, semiconductor quantum dots such as (Cd, Zn) (Se, S), and InP-based semiconductor quantum dots. The quantum dots may include at least one type selected from the group consisting of these. Here, a plurality of elements or cations separated by commas (,) in a formula representing the composition of the quantum dots means that at least one element among the plurality of elements or cations is contained in the composition.

### EXAMPLES

The present invention is specifically described below through examples; however, the present invention is not limited to these examples.

### Comparative Example 1

Through a known method, fluoride particles A1 were obtained as a phosphor having a composition represented by K₂[Si_{0.938}Mn_{0.062}F₆] with a Mn content percentage of 1.55 mass %.

### Example 1

To an aqueous sodium pyrophosphate solution (concentration 31.8 mmol/L) obtained by dissolving 1.61 g (3.61 mmol) of sodium pyrophosphate decahydrate in 113.4 g of pure water, 5.0 g of 35 mass % hydrogen peroxide water was added, and 100 g of the fluoride particles A1 of Comparative Example 1 was added while stirring at a rotation speed of 300 rpm using a stirring blade at room temperature (25° C.) to produce a phosphor slurry to be a reaction mother liquor.

Subsequently, an aqueous zinc sulfate solution (concentration 71.1 mmol/L) obtained by dissolving 1.56 g (5.42 mmol) of zinc sulfate heptahydrate in 76.3 g of pure water was added dropwise to the phosphor slurry at room temperature over about 1 minute. Stirring was stopped approximately 30 minutes after the dropwise addition was completed, and the mixture was allowed to stand at room temperature. Subsequently, the supernatant was removed, after which the precipitate was sufficiently washed with washing water containing 1 mass % of hydrogen peroxide. The obtained precipitate was subjected to solid-liquid separation, and then washed with ethanol and dried at 90° C. for 10 hours, whereby a fluoride phosphor E1 whose surface was covered with zinc phosphate was produced as Example 1.

### Example 2

A fluoride phosphor E2 of Example 2 was produced in the same as or similar manner as in Example 1 except that the dropwise addition time of the aqueous zinc sulfate solution was changed to about 120 minutes.

### Example 3

A fluoride phosphor E3 of Example 3 was produced in the same as or similar manner as in Example 2 except that the reaction temperature was changed to 2° C. The pH of the reaction mother liquor was 9 before the reaction, but decreased to 3.3 after the reaction.

### Example 4

A fluoride phosphor E4 of Example 4 was produced in the same as or similar manner as in Example 3 except that an aqueous sodium pyrophosphate solution (concentration 22.7 mmol/L) obtained by dissolving 0.44 g (0.99 mmol) of sodium pyrophosphate decahydrate in 43.5 g of pure water was used for the provision of the reaction mother liquor and an aqueous zinc sulfate solution (concentration 70.2 mmol/L) obtained by dissolving 0.42 g (1.46 mmol) of zinc sulfate heptahydrate in 20.8 g of pure water was used for the dropwise addition.

### Example 5

A fluoride phosphor E5 of Example 5 was produced in the same as or similar manner as in Example 3 except that an aqueous sodium pyrophosphate solution (concentration 31.8 mmol/L) obtained by dissolving 4.10 g (9.19 mmol) of sodium pyrophosphate decahydrate in 288.7 g of pure water was used for the provision of the reaction mother liquor and an aqueous zinc sulfate solution (concentration 70.9 mmol/L) obtained by dissolving 3.96 g (13.77 mmol) of zinc sulfate heptahydrate in 194.2 g of pure water was used for the dropwise addition.

### Example 6

A fluoride phosphor E6 of Example 6 was produced in the same as or similar manner as in Example 3 except that an aqueous sodium pyrophosphate solution (concentration 31.9 mmol/L) obtained by dissolving 2.20 g (4.93 mmol) of sodium pyrophosphate decahydrate in 154.6 g of pure water was used for the provision of the reaction mother liquor and an aqueous zinc sulfate solution (concentration 70.9 mmol/L) obtained by dissolving 2.12 g (7.37 mmol) of zinc sulfate heptahydrate in 104.0 g of pure water was used for the dropwise addition.

### Example 7

70 g of the fluoride phosphor E6 of Example 6 was weighed and placed into a solution obtained by mixing 130 ml of ethanol, 28.7 ml of ammonia water containing 16.2 mass % ammonia, and 7.0 g of 35 mass % hydrogen peroxide water. The mixture was stirred at a rotation speed of 300 rpm using a stirring blade, and the stirring was stopped after 2 hours. The obtained precipitate was subjected to solid-liquid separation, and then washed with ethanol and dried at 105° C. for 10 hours, whereby a fluoride phosphor E7 of Example 7 was produced.

### Example 8

The fluoride phosphor E7 of Example 7 was weighed in 60 g, and placed into a solution obtained by mixing 180 ml of ethanol and 24.6 ml of ammonia water containing 16.2 mass % of ammonia. The solution was stirred at a rotation speed of 300 rpm using a stirring blade while the solution temperature was maintained at room temperature to thereby obtain a reaction mother liquor. Tetraethoxysilane (TEOS: Si(OC₂H₅)₄) was weighed in 6.1 g, and was then added dropwise over a period of about 2 hours to the reaction mother liquor under stirring. Subsequently, stirring was continued for 1 hour, and 5 g of 35 mass % hydrogen peroxide (H₂O₂) were further added, after which the stirring was stopped. The obtained precipitate was subjected to solid-liquid separation, and then washed with ethanol and dried at 105° C. for 10 hours, whereby a fluoride phosphor E8 covered with silicon dioxide (SiO₂) was provided as Example 8. The amount of tetraethoxysilane added dropwise was approximately 3 mass % in terms of the silicon dioxide with respect to the fluoride particles.

### Manufacturing Example

Through a well-known method, fluoride particles were obtained as a phosphor having a composition represented by K₂[Si_{0.932}Mn_{0.068}F₆] with a Mn content percentage of 1.69 mass %. The obtained fluoride particles were weighed in 50 g and charged into a PTFE sample vessel (HUT-100R, manufactured by San-ai Chemical Industry Co., Ltd.). A liquid medium in an amount of 75 g provided by dissolving 300 g of KHF₂ in 450 g of a 65 mass % HF aqueous solution was supplied, the mixture was stirred to form a slurry, and then covered with a lid. The sample container covered with the lid was set in a stainless-steel outer cylinder (HUS-100, manufactured by San-ai Chemical Industry Co., Ltd.), and was subjected to a heating treatment in a thermostat at 190° C. for 16 hours. After the heating treatment was completed, the PTFE sample container was taken out from the stainless-steel outer cylinder. The obtained precipitate in the sample container was transferred to a beaker, washed by adding 600 ml of 1% hydrogen peroxide-water, subjected to solid-liquid separation, washed with ethanol, and dried at 90° C. for 10 hours, whereby fluoride particles A2 as a phosphor having a Mn content percentage of 1.53 mass % and having a first theoretical composition represented by K₂[Si_{0.938}Mn_{0.062}F₆] were produced.

### Example 9

A fluoride phosphor E9 of Example 9 was provided in the same as or similar manner as in Example 3 except that, for provision of the reaction mother liquor, a phosphor slurry to be the reaction mother liquor was produced using an aqueous sodium pyrophosphate solution (concentration 31.8 mmol/L) in which 2.34 g (5.25 mmol) of sodium pyrophosphate decahydrate was dissolved in 164.9 g of pure water and 100 g of the fluoride particles A2, and an aqueous zinc sulfate solution (concentration 71.0 mmol/L) in which 3.02 g (10.50 mmol) of zinc sulfate heptahydrate was dissolved in 148.0 g of pure water was used for dropwise addition.

### Evaluation

### (1) Zinc Content

The zinc content percentage of each of the obtained fluoride phosphors was analyzed by inductively coupled plasma atomic emission spectroscopy (ICP-AES) to determine the content percentage with respect to the fluoride phosphor (Zn analysis value). The results are presented in Table 1 below. In Table 1, “−” indicates no addition.

### (2) Scanning Electron Microscope Observation

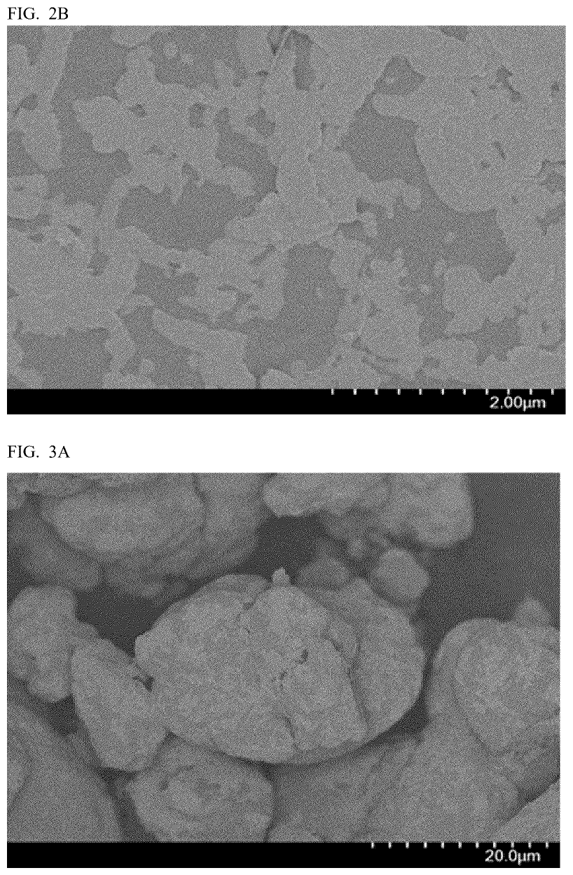

The fluoride phosphors obtained in Examples 1 to 3, 6, and 7 were subjected to image observation using a scanning electron microscope (SEM). The SEM images are presented in FIGS. 2A to 6B.

### (3) Amount of Silicon Dioxide

The composition of the obtained fluoride phosphor of Example 8 was analyzed by ICP emission spectrometry, the amount of silicon dioxide covering the fluoride particles was calculated from the difference in the analyzed Si concentration of the fluoride phosphor covered with silicon dioxide obtained in Example 8 and the analyzed Si concentration of the fluoride phosphor of Example 7, whereby the content percentage of silicon dioxide with respect to the fluoride phosphor (SiO₂ analysis value) was determined. The results are presented in Table 1 below. In Table 1, “−” indicates no addition.

### Manufacturing Example 1 of Light-Emitting Device

Each of the fluoride phosphors of Examples 1 to 5 and Comparative Example 1 was used as first phosphors. Each first phosphor was mixed with silicone resin so as to be 120 mass % with respect to the silicone resin to obtain a resin composition. Subsequently, a molded body having a recessed portion was provided, a light-emitting element formed of a gallium nitride compound semiconductor and having a light emission peak wavelength of 451 nm was disposed on a first lead at the bottom of the recessed portion, and then electrodes of the light-emitting element were connected to the first lead and a second lead by wires. Further, using a syringe, the resin composition was injected into the recessed portion of the molded body so as to cover the light-emitting element, then the resin composition was cured to form a wavelength conversion member, and a light-emitting device 1 was manufactured.

### Manufacturing Example 2 of Light-Emitting Device

Each of the fluoride phosphors of Examples 6 to 9 and Comparative Example 1 was used as a first phosphor. As a second phosphor, a nitride phosphor having a composition represented by (Ca, Sr)AlSiN₃:Eu and having a light emission peak wavelength in the vicinity of 625 nm was used in combination. A light-emitting device 2 was manufactured in the same as or similar manner as in Manufacturing Example 1 of a light-emitting device except that the first phosphor was mixed with silicone resin so as to be 70 mass % with respect to the silicone resin, and the second phosphor was mixed with silicone resin so as to be 60 mass % with respect to the silicone resin to obtain a resin composition.

### Durability Evaluation 1

The light-emitting device 1 using each of the fluoride phosphors obtained in Examples 1 to 5 and Comparative Example 1 was driven for 100 hours at a current value of 400 mA in an environmental tester at a temperature of 85° C. and a relative humidity of 85%, whereby durability evaluation 1 was performed. A luminous flux maintenance rate 1 (%) of the light-emitting device 1 after the durability evaluation 1 was determined based on the luminous flux of the light-emitting device 1 before the durability evaluation 1 being 100%. A higher luminous flux maintenance rate 1 indicates more excellent durability against high temperature and high humidity. The results are presented in Table 1 below. In Table 1, “−” indicates unevaluated.

### Durability Evaluation 2

The light-emitting device 2 using each of the fluoride phosphors obtained in Examples 6 to 9 and Comparative Example 1 was driven for 500 hours at a current value of 400 mA in an environmental tester at a temperature of 85° C. and a relative humidity of 85%, whereby durability evaluation 2 was performed. A luminous flux maintenance rate 2 (%) of the light-emitting device 2 after the durability evaluation 2 was determined based on the luminous flux of the light-emitting device 2 before the durability evaluation 2 being 100%. A higher luminous flux maintenance rate 2 indicates good durability against high temperature and high humidity. The results are presented in Table 1 below. In Table 1, “−” indicates unevaluated.

TABLE 1

| | | Fluoride phosphor | | | | | | Light- | Light- |
|---|---|---|---|---|---|---|---|---|---|
| | | | | Zinc | | | | emitting | emitting |
| | | Dropwise | | sulfate | | | | device 1 | device 2 |
| | | addition | Reaction | added | Alkali | Analysis value | | Luminous flux | Luminous flux |
| | Fluoride | time | temperature | amount | solution | (mass %) | | maintenance | maintenance |
| | particles | (min) | (° C.) | (mmol) | treatment | Zn | SiO₂ | rate 1 (%) | rate 2 (%) |
| Comparative | A1 | — | — | — | Not | — | — | 81.2 | 66.7 |
| Example 1 | | | | | performed | | | | |
| Example 1 | A1 | 1 | 25 | 5.42 | Not | 0.31 | — | 85.7 | — |
| | | | | | performed | | | | |
| Example 2 | A1 | 120 | 25 | 5.42 | Not | 0.33 | — | 89.7 | — |
| | | | | | performed | | | | |
| Example 3 | A1 | 120 | 2 | 5.42 | Not | 0.32 | — | 88.5 | — |
| | | | | | performed | | | | |
| Example 4 | A1 | 120 | 2 | 1.46 | Not | 0.01 | — | 83.1 | — |
| | | | | | performed | | | | |
| Example 5 | A1 | 120 | 2 | 13.77 | Not | 0.85 | — | 90.0 | — |
| | | | | | performed | | | | |
| Example 6 | A1 | 120 | 2 | 7.37 | Not | 0.43 | — | — | 83.7 |
| | | | | | performed | | | | |
| Example 7 | A1 | 120 | 2 | 7.37 | Performed | 0.44 | — | — | 85.5 |
| Example 8 | A1 | 120 | 2 | 7.37 | Performed | 0.42 | 2.8 | — | 90.8 |
| Example 9 | A2 | 120 | 2 | 10.5 | Not | 0.51 | — | — | 90.8 |
| | | | | | performed | | | | |

The luminous flux maintenance rates of the light-emitting devices 1 using the fluoride phosphor obtained in Examples 1 to 5 were higher than the luminous flux maintenance rate of the light-emitting device 1 using the fluoride phosphor of Comparative Example 1, and high durability was exhibited.

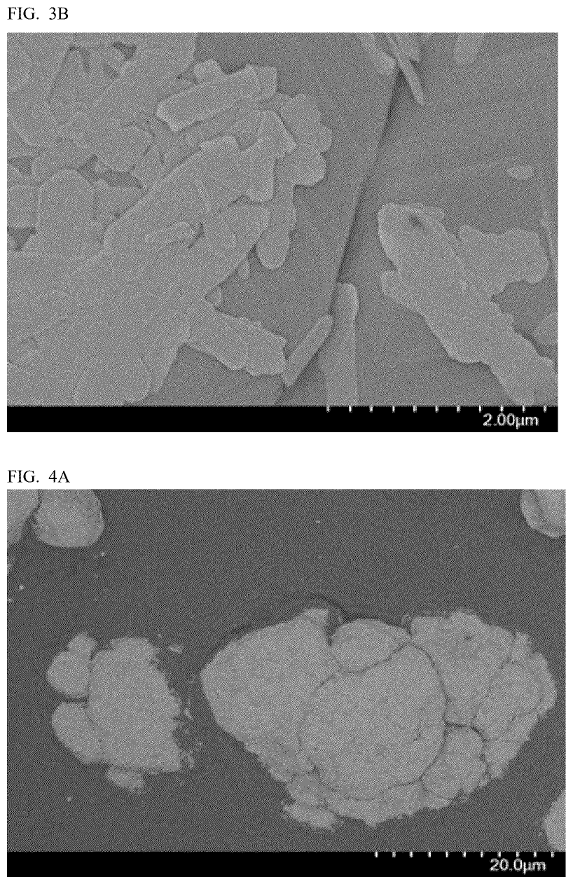

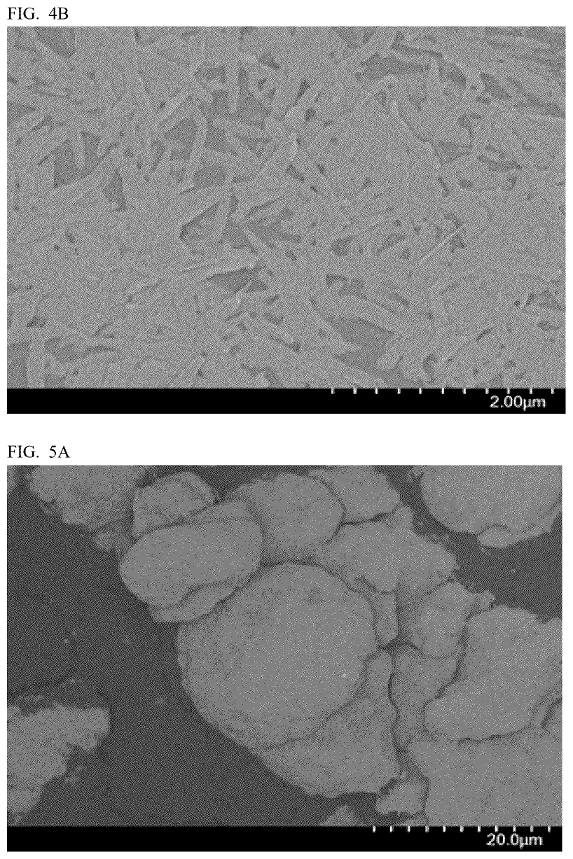

SEM images obtained by observing the fluoride phosphors obtained in Examples 1 to 3 with a scanning electron microscope are presented in FIGS. 2A, 2B, 3A, 3B, 4A, and 4B. The magnification in FIGS. 2A, 3A, and 4A is 2000 times, and the magnification in FIGS. 2B, 3B, and 4B is 25000 times. In each figure, the gray part corresponds to zinc phosphate, and the black part corresponds to the fluoride particles A1. This indicates that zinc phosphate is adhered to the fluoride particles in the fluoride phosphor. As illustrated in FIGS. 3A and 3B, when the dropwise addition time during the reaction was lengthened, the shape of the zinc phosphate became rod-shaped. In addition, as illustrated in FIGS. 4A and 4B, it can be seen that the particle size of zinc phosphate precipitated by cooling the reaction mother liquor decreases, and the zinc phosphate is adhered densely to the surface of the fluoride particles A1. The fluoride phosphors obtained in Examples 1 to 3 exhibited high durability by being covered with zinc phosphate.

When the surface of the light-emitting device 1 was observed after the durability evaluation 1, the resin was deteriorated in the light-emitting device 1 using the fluoride particles obtained in Comparative Example 1, whereas the deterioration of the resin was suppressed in the light-emitting devices 1 using the fluoride phosphors obtained in Examples 1 to 3. It is assumed that because zinc phosphate is adhered to the surface of the fluoride particles, the contact surface between the resin and the fluoride particles is reduced, and the deterioration of the resin is reduced, thus high durability is exhibited.

Zn analysis values of the fluoride phosphors of Examples 4 and 5 increased as the charged amount of zinc sulfate heptahydrate increased. The light-emitting device 1 using the fluoride particles obtained in Example 4 had a higher luminous flux maintenance rate 1 than the light-emitting device 1 using the fluoride particles obtained in Comparative Example 1. It can be seen that the effect can be obtained even when the adhesion amount of zinc phosphate is small. The light-emitting device 1 using the fluoride particles obtained in Example 5 is further improved in the luminous flux maintenance rate 1 as compared with the light-emitting device 1 using the fluoride particles obtained in Example 4, and it can be seen that when the reaction is performed under the same conditions, the higher the adhesion amount of zinc phosphate, the higher the durability.

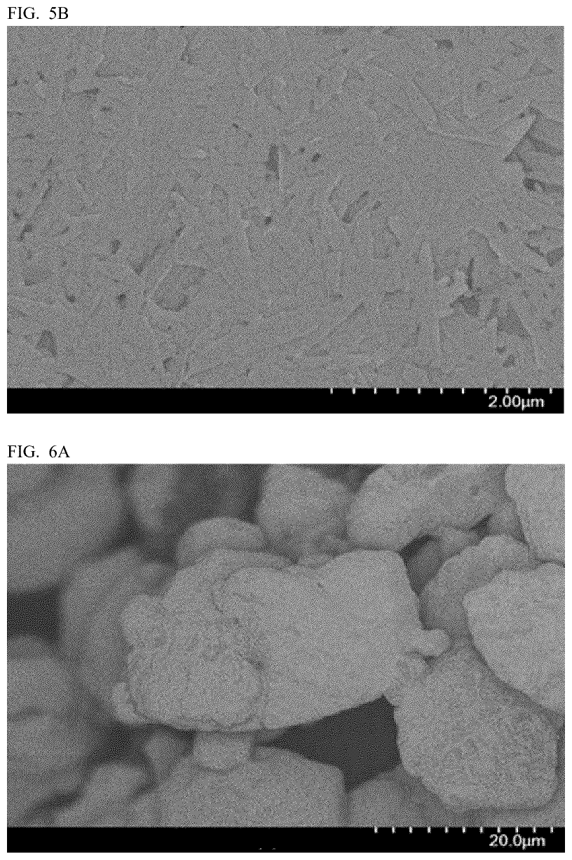

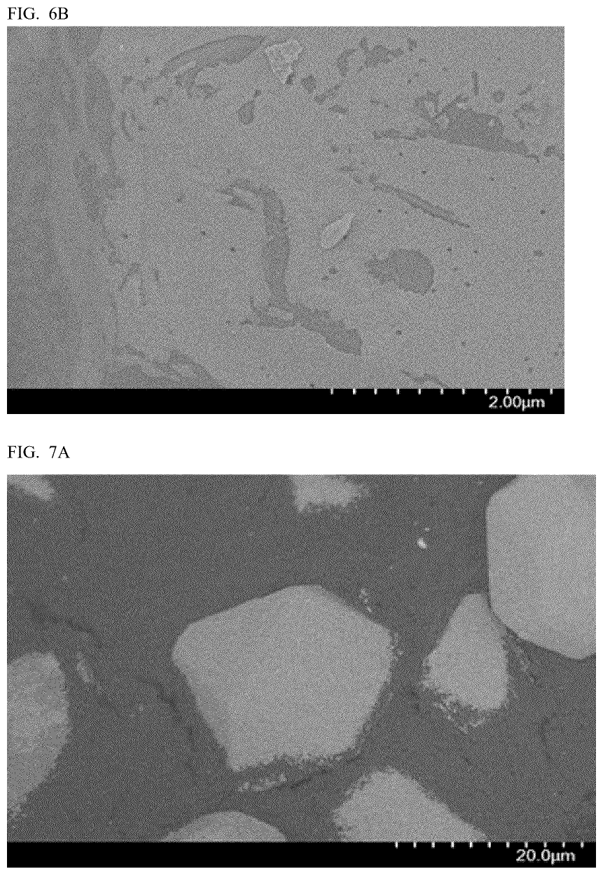

SEM images obtained by observing the fluoride phosphors provided in Examples 6 and 7 with a scanning electron microscope are presented in FIGS. 5A, 5B, 6A, and 6B. The magnification in FIGS. 5A and 6A is 2000 times, and the magnification in FIGS. 5B and 6B is 25000 times. In FIGS. 6A and 6B, zinc phosphate covering the fluoride particles are found to be forming a film. This seems to be because the zinc phosphate in a particle shape adhering to the fluoride particles in FIGS. 5A and 5B was dissolved in the alkaline solution and formed a film. The luminous flux maintenance rate 2 of the light-emitting device 2 using the fluoride phosphor of Example 7 is higher than the luminous flux maintenance rate 2 of the light-emitting device 2 using the fluoride phosphor of Example 6, and it is assumed that the gap between the zinc phosphate particles is filled or reduced by forming the zinc phosphate into a film, and the zinc phosphate particles are more uniformly adhered, thus high durability is exhibited.

The luminous flux maintenance rate of the light-emitting device 2 using the fluoride phosphor obtained in Example 8 was further improved as compared with the luminous flux maintenance rate 2 of the light-emitting device 2 using the fluoride phosphor obtained in Example 7. This is assumed to be because silicon oxide uniformly covers the fluoride phosphor to which zinc phosphate is adhered, the moisture resistance was further improved, and the elution from the fluoride particles was reduced, which reduced the deterioration due to the reaction between the eluate and the resin.

The luminous flux maintenance rate 2 of the light-emitting device 2 using the fluoride phosphor obtained in Example 9 was higher than the luminous flux maintenance rate 2 of the light-emitting device 2 using the fluoride particles obtained in Comparative Example 1, indicating higher durability.

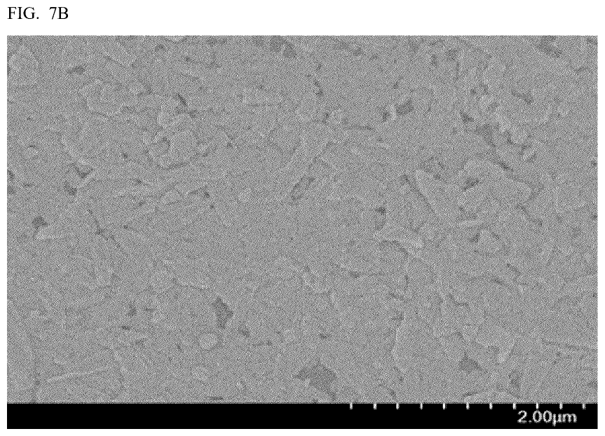

The SEM images of the fluoride phosphor obtained in Example 9 observed with a scanning electron microscope are presented in FIGS. 7A and 7B. As illustrated in FIG. 5A, zinc phosphate hardly adhered to the grain boundaries of the fluoride particles A1, but the fluoride particles A2 obtained through the autoclave treatment had few grain boundaries, and zinc phosphate was uniformly adhered. This is assumed to result in further reduction of the contact between the resins and the A2 of the fluoride particles and high durability. In addition, the number of small particles of the fluoride particles A2 that are easily deteriorated by moisture is also reduced, and this is also assumed to be a factor of improving the durability.

It is to be understood that although the present invention has been described with regard to preferred embodiments thereof, various other embodiments and variants may occur to those skilled in the art, which are within the scope and spirit of the invention, and such other embodiments and variants are intended to be covered by the following claims.

Although the present disclosure has been described with reference to several exemplary embodiments, it is to be understood that the words that have been used are words of description and illustration, rather than words of limitation. Changes may be made within the purview of the appended claims, as presently stated and as amended, without departing from the scope and spirit of the disclosure in its aspects. Although the disclosure has been described with reference to particular examples, means, and embodiments, the disclosure may be not intended to be limited to the particulars disclosed; rather the disclosure extends to all functionally equivalent structures, methods, and uses such as are within the scope of the appended claims.

One or more examples or embodiments of the disclosure may be referred to herein, individually and/or collectively, by the term “disclosure” merely for convenience and without intending to voluntarily limit the scope of this application to any particular disclosure or inventive concept. Moreover, although specific examples and embodiments have been illustrated and described herein, it should be appreciated that any subsequent arrangement designed to achieve the same or similar purpose may be substituted for the specific examples or embodiments shown. This disclosure may be intended to cover any and all subsequent adaptations or variations of various examples and embodiments. Combinations of the above examples and embodiments, and other examples and embodiments not specifically described herein, will be apparent to those of skill in the art upon reviewing the description.

In addition, in the foregoing Detailed Description, various features may be grouped together or described in a single embodiment for the purpose of streamlining the disclosure. This disclosure may be not to be interpreted as reflecting an intention that the claimed embodiments require more features than are expressly recited in each claim. Rather, as the following claims reflect, inventive subject matter may be directed to less than all of the features of any of the disclosed embodiments. Thus, the following claims are incorporated into the Detailed Description, with each claim standing on its own as defining separately claimed subject matter.

The above disclosed subject matter shall be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure may be determined by the broadest permissible interpretation of the following claims and their equivalents, and shall not be restricted or limited by the foregoing detailed description.

All publications, patent applications, and technical standards mentioned in this specification are herein incorporated by reference to the same extent as if each individual publication, patent application, or technical standard was specifically and individually indicated to be incorporated by reference.

What is claimed is:

1. A fluoride phosphor, comprising:
fluoride particles; and
a phosphate disposed on at least a part of a surface of the fluoride particles, wherein
the phosphate contains at least zinc, and
the fluoride particles have a composition containing an element M, an alkali metal, manganese, and a fluorine atom, wherein the element M comprises at least one element selected from the group consisting of Group 4 elements, Group 13 elements, and Group 14 elements, and when a number of moles of the alkali metal is 2, a number of moles of manganese is more than 0 and less than 0.2, a number of moles of the element M is more than 0.8 and less than 1, and a number of moles of the fluorine atom is more than 5 and less than 7.

2. The fluoride phosphor according to claim 1, wherein the first fluoride particles contain, in a composition thereof, silicon and/or germanium as the element M, and wherein in the composition, when the number of moles of the alkali metal is 2, a total number of moles of silicon, germanium, and manganese is in a range of 0.9 to 1.1.

3. The fluoride phosphor according to claim 1, wherein the fluoride particles have a composition represented by Formula (1): 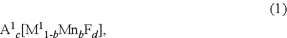
wherein in Formula (1), A¹ comprises at least one selected from the group consisting of Li, Na, K, Rb and Cs; M¹ contains Si and/or Ge and optionally at least one element selected from the group consisting of Group 4 elements and Group 14 elements; b satisfies 0<b<0.2, c is an absolute value of a charge of an [M¹_{1-b}Mn_{b}F_{d}] ion, and d satisfies 5<d<7.

4. The fluoride phosphor according to claim 1, wherein the phosphate is zinc phosphate.

5. The fluoride phosphor according to claim 1, wherein the phosphate has a zinc content of 0.01 mass % or more based on the fluoride phosphor.

6. The fluoride phosphor according to claim 1, wherein an oxide containing at least one selected from the group consisting of silicon, aluminum, titanium, zirconium, tin, and zinc is further disposed on at least a part of the surface of the fluoride particles.

7. The fluoride phosphor according to claim 6, wherein the oxide contains at least silicon.

8. The fluoride phosphor according to claim 7, wherein an average thickness of the oxide is 20 nm or more.

9. A method for manufacturing a fluoride phosphor, the method comprising:
providing first fluoride particles having a composition containing an element M, an alkali metal, manganese, and a fluorine atom, wherein the element M comprises at least one selected from the group consisting of Group 4 elements, Group 13 elements, and Group 14 elements, and wherein when a number of moles of the alkali metal is 2, a number of moles of manganese is more than 0 and less than 0.2, a number of moles of the element M is more than 0.8 and less than 1, and a number of moles of the fluorine atom is more than 5 and less than 7; and
bringing the first fluoride particles, phosphate ions, and at least one metal ion containing at least one element selected from the group consisting of magnesium, calcium, strontium, and zinc, into contact with each other in a liquid medium containing the first fluoride particles to obtain second fluoride particles in which a phosphate is adhered to the first fluoride particles.

10. The method according to claim 9, further comprising adjusting a pH of the liquid medium containing the first fluoride particles to be in a range of 3 to 9.

11. The method according to claim 9, the method further comprising:
obtaining third fluoride particles by bringing the second fluoride particles into contact with an alkaline liquid medium; and
bringing the third fluoride particles into contact with a metal alkoxide containing at least one selected from the group consisting of silicon, aluminum, titanium, zirconium, tin, and zinc in a liquid medium to dispose an oxide derived from the metal alkoxide onto at least a part of a surface of the third fluoride particles.

12. The method according to claim 9, wherein the first fluoride particles contain, in a composition thereof, silicon and/or germanium as the element M, and wherein in the composition, when the number of moles of the alkali metal is 2, a total number of moles of silicon, germanium, and manganese is in a range of 0.9 to 1.1.

13. The method according to claim 9, wherein the first fluoride particles have a composition represented by Formula (1): 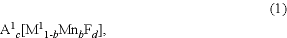
wherein in Formula (1), A¹ comprises at least one selected from the group consisting of Li, Na, K, Rb and Cs; M¹ contains Si and/or Ge and optionally at least one element selected from the group consisting of Group 4 elements and Group 14 elements; b satisfies 0<b<0.2, c is an absolute value of a charge of an [M¹_{1-b}Mn_{b}F_{d}] ion, and d satisfies 5<d<7.

14. A light-emitting device, comprising:
a wavelength conversion member comprising the fluoride phosphor according to claim 1 and a resin; and
a light-emitting element having a light emission peak wavelength in a range of 380 nm to 485 nm.
